(19) United States
(12) Patent Application Publication
(10) Pub. No.: US 2026/0059924 A1
(43) Pub. Date: Feb. 26, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-si (KR)

(72) Inventors: KIBUM KIM, Yongin-si (KR); SOOCHUL KIM, Yongin-si (KR); TAEGYUN KIM, Yongin-si (KR); Youngchul Sim, Yongin-si (KR); SOYOUNG LEE, Yongin-si (KR); WONHO LEE, Yongin-si (KR)

(21) Appl. No.: 19/227,413

(22) Filed: Jun. 3, 2025

(30) Foreign Application Priority Data
Aug. 20, 2024 (KR) 10-2024-0111444

(51) Int. Cl. H10H 29/856; H10H 29/01; H10H 29/80; H10H 29/855

(52) U.S. Cl. CPC H10H 29/856; H10H 29/032; H10H 29/0363; H10H 29/8325; H10H 29/855

(57) ABSTRACT

A display device includes: a substrate; a first reflective layer on the substrate and including at least one lower sub-insulating layer which includes a first sub-layer having a first refractive index and a second sub-layer on the first sub-layer and having a second refractive index different from the first refractive index; a first light-emitting element on the first reflective layer and configured to emit light of a first color; a first reflective bulkhead spaced apart from the first light-emitting element and provided at opposite sides of the first light-emitting element; and a reflective electrode under the first light-emitting element and overlapping the first reflective bulkhead in a plan view.

### CROSS-REFERENCE TO RELATED APPLICATION

The present application claims priority to and the benefit of Korean Patent Application No. 10-2024-0111444, filed on Aug. 20, 2024, in the Korean Intellectual Property Office, the entire content of which is incorporated herein by reference.

### BACKGROUND

### 1. Field

One or more aspects of embodiments of the present disclosure relate generally to a display device. More particularly, one or more aspects of embodiments of the present disclosure relate to a display device, a method of manufacturing the display device, and an electronic device including the display device.

### 2. Description of the Related Art

A light emitting diode (LED) is an element that can convert an electrical signal into a form of light such as infrared light, visible light, and/or the like by utilizing the characteristics of a compound semiconductor. For example, a light emitting diode may be a semiconductor element in which, when a voltage is applied to a P-N diode in a forward direction, holes and electrons are injected, and the energy generated by the recombination of holes and electrons is converted into light energy. Research to improve the light efficiency of the light emitting diode is continuously on-going.

### SUMMARY

One or more aspects of the present embodiments provide a display device with improved display quality.

One or more aspects of the present embodiments provide a method of manufacturing the display device.

One or more aspects of the present embodiments provide an electronic device including the display device.

A display device according to one or more embodiments of the present disclosure includes: a substrate; a first reflective layer on the substrate and including at least one lower sub-insulating layer which includes a first sub-layer having a first refractive index and a second sub-layer on the first sub-layer and having a second refractive index different from the first refractive index; a first light-emitting element on the first reflective layer and configured to emit light of a first color; a first reflective bulkhead spaced apart from the first light-emitting element and provided at opposite sides of the first light-emitting element; and a reflective electrode under the first light-emitting element and overlapping the first reflective bulkhead in a plan view.

In one or more embodiments, the reflective electrode may overlap a spaced area between the first light-emitting element and the first reflective bulkhead in the plan view.

In one or more embodiments, the display device may further include a first adhesive pattern between the first reflective layer and the first light-emitting element.

In one or more embodiments, the reflective electrode may overlap a spaced area between the first adhesive pattern and the first reflective bulkhead in the plan view.

In one or more embodiments, the first adhesive pattern may be spaced apart from the first reflective bulkhead.

In one or more embodiments, the first adhesive pattern may include a conductive material.

In one or more embodiments, the first reflective layer may overlap the first light-emitting element in the plan view.

In one or more embodiments, the reflective electrode may be under the first reflective layer.

In one or more embodiments, the reflective electrode may be on the first reflective layer.

In one or more embodiments, the reflective electrode may contact the first reflective bulkhead.

In one or more embodiments, the display device may further include a second light-emitting element on the first light-emitting element and configured to emit light of a second color different from the first color, a second reflective bulkhead spaced apart from the second light-emitting element and provided at opposite sides of the second light-emitting element, and a second reflective layer between the first light-emitting element and the second light-emitting element, the second reflective layer overlapping the second light-emitting element in the plan view, and including at least one middle sub-insulating layer which includes the first sub-layer and the second sub-layer on the first sub-layer.

In one or more embodiments, the display device may further include a third light-emitting element on the second light-emitting element and configured to emit light of a third color different from the first color and the second color, a third reflective bulkhead spaced apart from the third light-emitting element and provided at opposite sides of the third light-emitting element, and a third reflective layer between the second light-emitting element and the third light-emitting element, the third reflective layer overlapping the third light-emitting element in the plan view, and including at least one upper sub-insulating layer which includes the first sub-layer and the second sub-layer on the first sub-layer.

In one or more embodiments, the first reflective layer may overlap the first light-emitting element, the second light-emitting element, and the third light-emitting element in the plan view.

In one or more embodiments, the first reflective layer may overlap the first light-emitting element in the plan view and may not overlap the second light-emitting element and the third light-emitting element in the plan view.

A method of manufacturing a display device according to one or more embodiments of the present disclosure includes: forming reflective electrodes spaced apart from each other on a substrate; forming a first reflective layer including at least one lower sub-insulating layer which includes a first sub-layer having a first refractive index and a second sub-layer on the first sub-layer and having a second refractive index different from the first refractive index on the substrate; forming a first light-emitting element configured to emit light of a first color on the first reflective layer so as to overlap a spaced area between the reflective electrodes in a plan view; forming a first insulating layer covering the first light-emitting element on the first reflective layer; forming a lower contact hole which penetrates the first insulating layer at opposite sides of the first light-emitting element; and forming a first reflective bulkhead which fills an interior of the lower contact hole.

In one or more embodiments, the first reflective layer may be formed on the reflective electrodes after forming the reflective electrodes on the substrate.

In one or more embodiments, the reflective electrodes may be formed on the first reflective layer after forming the first reflective layer on the substrate.

In one or more embodiments, the method may further include forming a first adhesive pattern on the first reflective layer. The first adhesive pattern may be formed between at least one of the reflective electrodes and the first light-emitting element.

In one or more embodiments, at least one of the reflective electrodes may overlap a spaced area between the first adhesive pattern and the first reflective bulkhead in the plan view.

An electronic device according to one or more embodiments of the present disclosure includes: a display device including a light-emitting element; and a processor configured to transmit an image data signal and an input control signal to the display device. The display device includes: a substrate; a first reflective layer on the substrate and including at least one lower sub-insulating layer which includes a first sub-layer having a first refractive index and a second sub-layer on the first sub-layer and having a second refractive index different from the first refractive index; the light-emitting element on the first reflective layer and configured to emit light; a first reflective bulkhead spaced apart from the light-emitting element and provided at opposite sides of the light-emitting element; and a reflective electrode under the light-emitting element and overlapping the first reflective bulkhead in a plan view.

A display device according to one or more embodiments of the present disclosure may include a light-emitting element, an adhesive pattern for attaching the light-emitting element to a lower structure of the light-emitting element, a reflective bulkhead provided at opposite sides of the light-emitting element, and a reflective electrode under the light-emitting element. The reflective electrode may overlap a spaced area between the adhesive pattern and the reflective bulkhead in a plan view.

The reflective electrode may reflect light traveling in a spaced space (e.g., spaced area) between the adhesive pattern and the reflective bulkhead in a desired or suitable direction (e.g., a front direction of the display device). Accordingly, a problem of light loss due to light reflected from the reflective bulkhead traveling to the spaced space between the adhesive pattern and the reflective bulkhead may be effectively or suitably prevented or reduced.

A display device according to one or more embodiments of the present disclosure may further include a reflective layer under the light-emitting element and overlapping the light-emitting element in a plan view. The reflective layer may include a distributed Bragg reflective layer in which a first sub-layer and a second sub-layer having different refractive indices are alternately and repeatedly stacked. Accordingly, the reflective layer may reflect light toward the reflective layer by the light-emitting element in a desired or suitable direction, and the light efficiency of the light-emitting element may be improved.

### BRIEF DESCRIPTION OF THE DRAWINGS

Illustrative, non-limiting embodiments will be more clearly understood from the following detailed description in conjunction with the accompanying drawings, in which:

FIG. 1 is a plan view illustrating a display device according to one or more embodiments of the present disclosure.

FIG. 2 is an enlarged plan view of area A of FIG. 1.

FIG. 3 is a cross-sectional view taken along the line I-I′ of FIG. 1.

FIG. 4 is an enlarged cross-sectional view of area B of FIG. 3.

FIG. 5 is a cross-sectional view illustrating a display device according to one or more embodiments of the present disclosure.

FIGS. 6, 7, 8, 9, 10, 11, 12, 13, 14, 15, 16, 17, and 18 are cross-sectional views illustrating a method of manufacturing a display device according to one or more embodiments of the present disclosure.

FIG. 19 is a block diagram of an electronic device according to one or more embodiments of the present disclosure.

FIG. 20 is a schematic diagram of an electronic device according to one or more suitable embodiments.

### DETAILED DESCRIPTION

Hereinafter, embodiments of the present disclosure will be described in more detail with reference to the accompanying drawings. The same reference numerals are used for the same components in the drawings, and redundant descriptions of the same components will not be provided.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,”“utilizing,”and “utilized,”respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to”another element, there are no intervening elements present.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above”or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

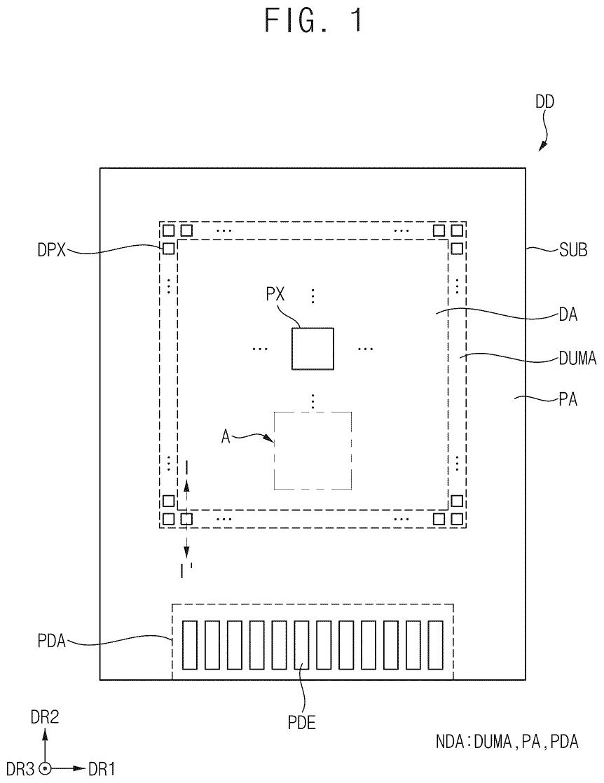

FIG. 1 is a plan view illustrating a display device according to one or more embodiments of the present disclosure.

In this specification, a plane may be defined by a first direction DR1 and a second direction DR2 intersecting the first direction DR1. For example, the first direction DR1 and the second direction DR2 may be perpendicular (or substantially perpendicular) to each other. A direction normal to the plane, that is, a thickness direction of a display device DD may be a third direction DR3. For example, the third direction DR3 may be perpendicular (or substantially perpendicular) to each of the first direction DR1 and the second direction DR2. As used herein the term “in a plan view” is a view in (along) the third direction DR3.

Referring to FIG. 1, the display device DD according to one or more embodiments of the present disclosure may include a substrate SUB, pixels PX, dummy pixels DPX, and pad electrodes PDE.

The substrate SUB may include a display area DA and a non-display area NDA. The display area DA may be defined as an area that displays an image by generating light and/or adjusting the transmittance of light provided from an external light source. The pixels PX may be provided in the display area DA on the substrate SUB. Each of the pixels PX may generate light in response to a driving signal. For example, the pixels PX may be provided in a matrix form along the first direction DR1 and the second direction DR2.

The non-display area NDA may be defined as an area that does not display an image. Drivers for displaying an image in the display area DA may be provided in the non-display area NDA. The non-display area NDA may include a dummy pixel area DUMA, a peripheral area PA, and a pad area PDA.

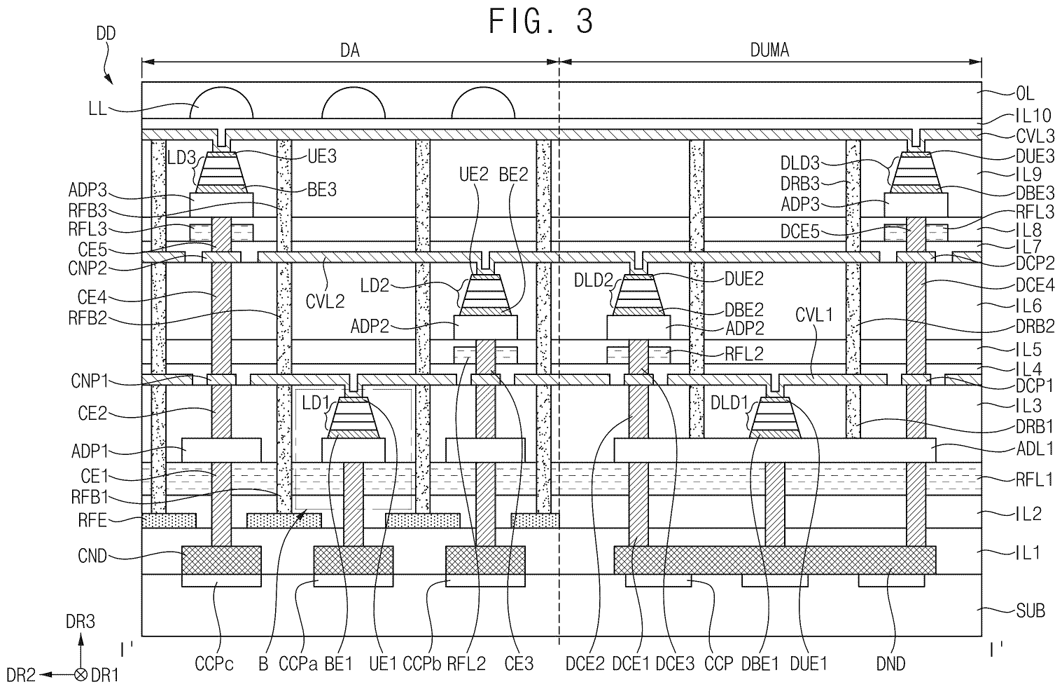

The dummy pixel area DUMA may surround the display area DA in a plan view. For example, the dummy pixel area DUMA may entirely surround the display area DA in a plan view. The dummy pixel area DUMA may be formed in consideration of the process deviation that may occur in the manufacturing process of the display device DD. For example, the dummy pixel area DUMA may be formed to entirely surround the pixels PX and may serve as a buffer area. The dummy pixels DPX may be provided in the dummy pixel area DUMA on the substrate SUB. The dummy pixels DPX may be provided repeatedly with each other along a border of the dummy pixel area DUMA. The dummy pixels DPX may include substantially the same or similar electrodes and contact holes as those included in the pixels PX. A detailed description thereof will be provided herein below with reference to FIG. 3.

The peripheral area PA may be located around the display area DA and the dummy pixel area DUMA. The peripheral area PA may surround at least a portion of the dummy pixel area DUMA in a plan view. For example, the peripheral area PA may entirely surround the dummy pixel area DUMA in a plan view.

The pad area PDA may be spaced apart from the display area DA and the dummy pixel area DUMA in one direction. For example, the pad area PDA may be spaced apart from the display area DA and the dummy pixel area DUMA in the second direction DR2. The pad electrodes PDE may be provided in the pad area PDA on the substrate SUB. In some embodiments, a printed circuit board may be provided in the pad area PDA on the substrate SUB, and may be connected to the pad electrodes PDE through an anisotropic conductive film. For example, the printed circuit board may be a flexible printed circuit board (FPCB).

In one or more embodiments, the display device DD may be a micro LED display device. For example, each of the pixels PX may include a light-emitting element that generates light, and the light-emitting element may be a micro light-emitting diode. However, the present disclosure is not limited thereto, and the display device DD may be any one selected from among an organic light-emitting display device, a liquid crystal display device, an organic light-emitting diode on silicon (OLEDoS), an inorganic light-emitting display device, and a quantum dot emitting display device.

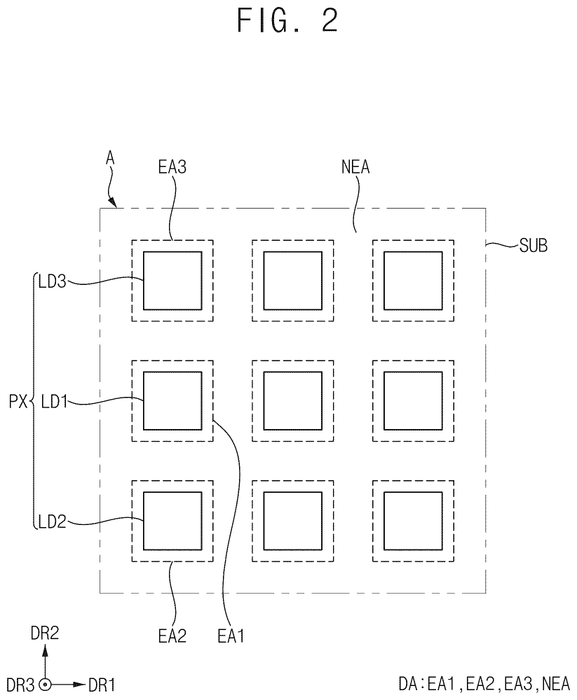

FIG. 2 is an enlarged plan view of area A of FIG. 1.

Referring to FIG. 2, the substrate SUB may include the display area DA, and the display area DA may include a first light-emitting area EA1, a second light-emitting area EA2, a third light-emitting area EA3, and a non-emitting area NEA. Each of the pixels PX may include first to third light-emitting elements LD1, LD2, and LD3 that are to emit light.

The first to third light-emitting elements LD1, LD2, and LD3 may be to emit light of different colors. For example, the first light-emitting element LD1 may be to emit green light, the second light-emitting element LD2 may be to emit blue light, and the third light-emitting element LD3 may be to emit red light. However, the present disclosure is not limited thereto.

Although each of the pixels PX is illustrated in FIG. 2 as including three light-emitting elements LD1, LD2, and LD3 that emit light of different colors, the present disclosure is not limited thereto.

In one or more embodiments, each of the first to third light-emitting elements LD1, LD2, and LD3 may be a micro light-emitting diode, but the present disclosure is not limited thereto.

The first to third light-emitting areas EA1, EA2, and EA3 may be areas where light is emitted (or configured to be emitted) by the light-emitting elements. For example, the first light-emitting element LD1 may be provided in the first light-emitting area EA1, and the first light-emitting area EA1 may be an area where light is emitted (or configured to be emitted) by the first light-emitting element LD1. In one or more embodiments, the second light-emitting element LD2 may be provided in the second light-emitting area EA2, and the second light-emitting area EA2 may be an area where light is emitted (or configured to be emitted) by the second light-emitting element LD2. In one or more embodiments, the third light-emitting element LD3 may be provided in the third light-emitting area EA3, and the third light-emitting area EA3 may be an area where light is emitted (or configured to be emitted) by the third light-emitting element LD3. For example, the first light-emitting area EA1 may be to emit green light, the second light-emitting area EA2 may be to emit blue light, and the third light-emitting area EA3 may be to emit red light.

For example, each of the first to third light-emitting areas EA1, EA2, and EA3 may have a planar shape selected from among triangular, rectangular, circular, oval, track-shaped, and/or the like. In one or more embodiments, each of the first to third light-emitting areas EA1, EA2, and EA3 may have a rectangular planar shape. For example, the first to third light-emitting areas EA1, EA2, and EA3 may have the same planar shape as each other. However, the present disclosure is not limited thereto, and the first to third light-emitting areas EA1, EA2, and EA3 may have different planar shapes.

For example, the first to third light-emitting areas EA1, EA2, and EA3 may have the same size (and/or area) as each other. However, the present disclosure is not limited thereto, and the first to third light-emitting areas EA1, EA2, and EA3 may have different sizes (and/or areas).

For example, the first to third light-emitting areas EA1, EA2, and EA3 may be provided in an order of the second light-emitting area EA2, the first light-emitting area EA1, and the third light-emitting area EA3 along the second direction DR2, but the present disclosure is not limited thereto. The arrangement relationship of the first to third light-emitting areas EA1, EA2, and EA3 may be suitably varied according to one or more embodiments.

The non-emitting area NEA may be between the first to third light-emitting areas EA1, EA2, and EA3. For example, the non-emitting area NEA may surround the first to third light-emitting areas EA1, EA2, and EA3 in a plan view. For example, the non-emitting area NEA may have a mesh shape, a net shape, a lattice shape, and/or the like in a plan view. The non-emitting area NEA may be defined as an area where light is not emitted.

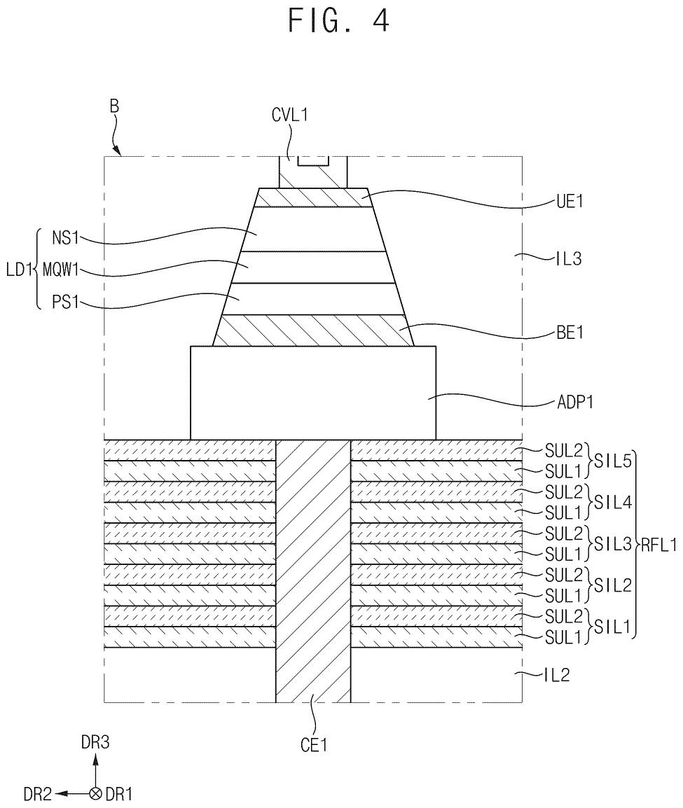

FIG. 3 is a cross-sectional view taken along the line I-I′ of FIG. 1. For example, FIG. 3 is a cross-sectional view illustrating the dummy pixel area DUMA and the display area DA adjacent to the dummy pixel area DUMA. FIG. 4 is an enlarged cross-sectional view of area B of FIG. 3.

Referring to FIGS. 3 and 4, the display device DD according to one or more embodiments of the present disclosure may include a lower layer including the first light-emitting element LD1, a middle layer on the lower layer and including the second light-emitting element LD2, and an upper layer on the middle layer and including the third light-emitting element LD3. The first light-emitting element LD1, the second light-emitting element LD2, and the third light-emitting element LD3 may be spaced apart from each other in a plan view.

The lower layer may include the substrate SUB, a connection pad CND, a dummy connection pad DND, first to third insulating layers IL1, IL2, and IL3, a reflective electrode RFE, first and second connection electrodes CE1 and CE2, first and second dummy connection electrodes DCE1 and DCE2, a first reflective layer RFL1, a first adhesive layer ADL1, a first lower electrode BE1, the first light-emitting element LD1, a first upper electrode UE1, a first dummy lower electrode DBE1, a first dummy light-emitting element DLD1, a first dummy upper electrode DUE1, a first reflective bulkhead RFB1, a first dummy reflective bulkhead DRB1, a first common voltage line CVL1, a first connection pattern CNP1, and a first dummy connection pattern DCP1.

The middle layer may include fourth to sixth insulating layers IL4, IL5, and IL6, third and fourth connection electrodes CE3 and CE4, third and fourth dummy connection electrodes DCE3 and DCE4, a second reflective layer RFL2, a second adhesive pattern ADP2, a second lower electrode BE2, the second light-emitting element LD2, a second upper electrode UE2, a second dummy lower electrode DBE2, a second dummy light-emitting element DLD2, a second dummy upper electrode DUE2, a second reflective bulkhead RFB2, a second dummy reflective bulkhead DRB2, a second common voltage line CVL2, a second connection pattern CNP2, and a second dummy connection pattern DCP2.

The upper layer may include seventh to tenth insulating layer IL7, IL8, IL9, and IL10, a fifth connection electrode CE5, a fifth dummy connection electrode DCE5, a third reflective layer RFL3, a third adhesive pattern ADP3, a third lower electrode BE3, the third light-emitting element LD3, a third upper electrode UE3, a third dummy lower electrode DBE3, a third dummy light-emitting element DLD3, a third dummy upper electrode DUE3, a third reflective bulkhead RFB3, a third dummy reflective bulkhead DRB3, a third common voltage line CVL3, a lens layer LL, and a filling layer OL.

The substrate SUB may include a transparent material or an opaque material. The substrate may be formed of a transparent resin substrate. A polyimide substrate may be an example of the transparent resin substrate. In one or more embodiments, the substrate SUB may include silicon (Si). For example, the substrate SUB may be a silicon wafer. However, the present disclosure is not limited thereto, and the substrate SUB may include gallium nitride (GaN), sapphire, gallium arsenide (GaAs), zinc oxide (ZnO), and/or the like. These may be used alone or in combination with each other.

Circuit portions CCP may be mounted on the substrate SUB. For example, the substrate SUB may define grooves, and the circuit portions CCP may be accommodated in the grooves, respectively. The circuit portions CCP may include first to third pixel driving circuits CCPa, CCPb, and CCPc. Each of the first to third pixel driving circuits CCPa, CCPb, and CCPc may include at least one transistor and at least one capacitor. The first pixel driving circuit CCPa may be electrically connected to the first light-emitting element LD1, the second pixel driving circuit CCPb may be electrically connected to the second light-emitting element LD2, and the third pixel driving circuit CCPc may be electrically connected to the third light-emitting element LD3.

The connection pads CND may be provided in the display area DA on the substrate SUB. The connection pads CND may be electrically connected to the first to third pixel driving circuits CCPa, CCPb, and CCPc. The connection pads CND may be spaced apart from each other. For example, the connection pads CND may be spaced apart from each other in the second direction DR2 in the display area DA. The connection pads CND may include a conductive material such as a metal, an alloy, a conductive metal nitride, a conductive metal oxide, a transparent conductive oxide, and/or the like. Examples of the conductive material that may be used as the connection pads CND may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These may be used alone or in combination with each other.

The dummy connection pad DND may be provided in the dummy pixel area DUMA on the substrate SUB. The dummy connection pad DND may be electrically connected to the circuit portions CCP. In one or more embodiments, the dummy connection pad DND may include the same material as the connection pads CND and may be formed through substantially the same process as the connection pads CND.

The first insulating layer IL1 may be on the substrate SUB. The first insulating layer IL1 may cover the connection pads CND and the dummy connection pad DND. The first insulating layer IL1 may include an inorganic insulating material and/or an organic insulating material. Examples of the inorganic insulating material that may be used as the first insulating layer IL1 may include silicon oxide (SiOₓ, where 0<x≤2), silicon nitride (SiNₓ, where 0<x≤2), silicon oxynitride (SiOₓN_{y}, where 0<x≤2 and 0<y≤2), and/or the like. These may be used alone or in combination with each other. Examples of the organic insulating material that may be used as the first insulating layer IL1 may include a polyacryl-based resin, a polyimide-based resin, a polyamide-based resin, a siloxane-based resin, an acrylic-based resin, an epoxy-based resin, and/or the like. These may be used alone or in combination with each other.

The reflective electrode RFE may be provided in the display area DA on the first insulating layer IL1. The reflective electrode RFE may be under the first light-emitting element LD1. The reflective electrode RFE may not be provided in the dummy pixel area DUMA.

In one or more embodiments, the reflective electrode RFE may overlap a spaced area between the light-emitting element and the reflective bulkhead in a plan view. For example, the reflective electrode RFE may overlap a spaced area between the first light-emitting element LD1 and the first reflective bulkhead RFB1 in a plan view. In one or more embodiments, the reflective electrode RFE may overlap a spaced area between the second light-emitting element LD2 and the second reflective bulkhead RFB2 in a plan view. In one or more embodiments, the reflective electrode RFE may overlap a spaced area between the third light-emitting element LD3 and the third reflective bulkhead RFB3 in a plan view. For example, the reflective electrode RFE may have a grid shape and/or a matrix shape in a plan view.

In one or more embodiments, the reflective electrode RFE may include a metal with suitably high light reflectance. For example, the reflective electrode RFE may include aluminum (Al) and/or silver (Ag), but the present disclosure is not limited thereto.

The second insulating layer IL2 may be on the first insulating layer IL1. The second insulating layer IL2 may cover the reflective electrode RFE. The second insulating layer IL2 may include an inorganic insulating material and/or an organic insulating material.

The first reflective layer RFL1 may be on the substrate SUB. For example, the first reflective layer RFL1 may be on the second insulating layer IL2. In one or more embodiments, the first reflective layer RFL1 may be under the first light-emitting element LD1. In one or more embodiments, as illustrated in FIG. 3, the first reflective layer RFL1 may be entirely over the display area DA and the dummy pixel area DUMA. In this case, the first reflective layer RFL1 may overlap the first light-emitting element LD1, the second light-emitting element LD2, and the third light-emitting element LD3 in a plan view. However, the present disclosure is not limited thereto.

In one or more embodiments, the first reflective layer RFL1 may be provided in only a portion of the display area DA. For example, the first reflective layer RFL1 may be under the first light-emitting element LD1, and may overlap the first light-emitting element LD1 in a plan view, and may not overlap the second light-emitting element LD2 and the third light-emitting element LD3 in a plan view.

In one or more embodiments, the first reflective layer RFL1 may be on the reflective electrode RFE. However, the present disclosure is not limited thereto, and the first reflective layer RFL1 may be provided both (e.g., simultaneously) at an upper portion of the reflective electrode RFE and at a lower portion of the reflective electrode RFE. For example, the first reflective layer RFL1 may include a first lower reflective layer provided at the lower portion of the reflective electrode RFE and a first upper reflective layer provided at the upper portion of the reflective electrode RFE. In this case, the reflective electrode RFE may be surrounded by the first lower reflective layer and the first upper reflective layer.

As illustrated in FIG. 4, the first reflective layer RFL1 may include at least one lower sub-insulating layer. The lower sub-insulating layer may have a structure in which two or more sub-layers having different refractive indices are stacked. For example, the first reflective layer RFL1 may include at least one lower sub-insulating layer in which a first sub-layer SUL1 and a second sub-layer SUL2 having different refractive indices are sequentially stacked. For example, the first reflective layer RFL1 may include first to fifth sub-insulating layers SIL1, SIL2, SIL3, SIL4, and SIL5 that are sequentially stacked along the third direction DR3.

For example, each of the first to fifth sub-insulating layers SIL1, SIL2, SIL3, SIL4, and SIL5 may include the first sub-layer SUL1 and the second sub-layer SUL2 sequentially stacked along the third direction DR3. The first sub-layer SUL1 may include a first inorganic film having a first refractive index, and the second sub-layer SUL2 may include a second inorganic film having a second refractive index different from the first refractive index. For example, the first reflective layer RFL1 may include a distributed Bragg reflective layer in which the first sub-layer SUL1 having the first refractive index and the second sub-layer SUL2 having the second refractive index are alternately and repeatedly stacked. For example, the first reflective layer RFL1 may include multiple first and second sub-layers SUL1 and SUL alternating with each other.

In one or more embodiments, the first refractive index of the first sub-layer SUL1 may be smaller than the second refractive index of the second sub-layer SUL2. In some embodiments, the first sub-layer SUL1 may include silicon oxide (SiOₓ), and the second sub-layer SUL2 may include niobium oxide (NbOₓ) and/or titanium oxide (TiOₓ). However, the present disclosure is not limited thereto.

In one or more embodiments, the first refractive index of the first sub-layer SUL1 may be greater than the second refractive index of the second sub-layer SUL2. In this case, the first sub-layer SUL1 may include niobium oxide (NbOₓ) and/or titanium oxide (TiOₓ), and the second sub-layer SUL2 may include silicon oxide (SiOₓ).

According to the present embodiments, by forming the first reflective layer RFL1 such that the first sub-layer SUL1 and the second sub-layer SUL2 having different refractive indices are alternately stacked, a difference in refractive index may be repeatedly formed within the first reflective layer RFL1. By controlling the component material, the thickness, and/or the number of layers of the first sub-layer SUL1 and the second sub-layer SUL2, the reflectivity of light incident on the first reflective layer RFL1 may be improved. For example, the thickness and/or the number of layers of the first sub-layer SUL1 and the second sub-layer SUL2 may be determined in consideration of a wavelength of light (e.g., green light) to be emitted by the first light-emitting element LD1. Accordingly, the first reflective layer RFL1 may reflect light emitted toward the first reflective layer RFL1 by the first light-emitting element LD1 in a desired or suitable direction (e.g., a front direction of the display device DD), and the light efficiency of the first light-emitting element LD1 may be improved.

As illustrated in FIG. 3, the first connection electrode CE1 may be provided in the display area DA on the connection pad CND. The first connection electrode CE1 may be provided in a first through hole that penetrates the first insulating layer IL1, the second insulating layer IL2, and the first reflective layer RFL1 in the display area DA. The first connection electrode CE1 may contact the connection pad CND. Accordingly, the first connection electrode CE1 may be electrically connected to any one selected from among the first to third pixel driving circuits CCPa, CCPb, and CCPc. The first connection electrode CE1 may include a conductive material such as a metal, an alloy, a conductive metal nitride, a conductive metal oxide, a transparent conductive oxide, and/or the like. In one or more embodiments, the first connection electrode CE1 may include copper (Cu), titanium (Ti), titanium nitride (TiN), and/or tungsten (W), but the present disclosure is not limited thereto.

The first dummy connection electrode DCE1 may be provided in the dummy pixel area DUMA on the dummy connection pad DND. The first dummy connection electrode DCE1 may be provided in a first dummy through hole that penetrates the first insulating layer IL1, the second insulating layer IL2, and the first reflective layer RFL1 in the dummy pixel area DUMA. The first dummy connection electrode DCE1 may contact the dummy connection pad DND. In one or more embodiments, the first dummy connection electrode DCE1 may include the same material as the first connection electrode CE1 and may be formed through substantially the same process as the first connection electrode CE1.

The first adhesive layer ADL1 may be on the first reflective layer RFL1. The first adhesive layer ADL1 may be on (e.g., in) the display area DA and the dummy pixel area DUMA. The first adhesive layer ADL1 may include a conductive material, such as a metal, an alloy, and/or the like. For example, the first adhesive layer ADL1 may include gold (Au), tin (Sn), silver (Ag), aluminum (Al), titanium (Ti), and/or the like. In one or more embodiments, the first adhesive layer ADL1 may include a tin (Sn)-gold (Au) alloy, but the present disclosure is not limited thereto.

The first adhesive layer ADL1 may include first adhesive patterns ADP1 that are spaced apart from each other in the display area DA. For example, the first adhesive patterns ADP1 may be spaced apart from each other in the second direction DR2. The first adhesive patterns ADP1 may be formed by patterning the first adhesive layer ADL1. Each of the first adhesive patterns ADP1 may contact the first connection electrode CE1. Each of the first adhesive patterns ADP1 may be spaced apart from the first reflective bulkhead RFB1.

The first lower electrode BE1 may be on the first adhesive pattern ADP1. For example, the first lower electrode BE1 may be provided at an upper surface of the first adhesive pattern ADP1 that is electrically connected to the first pixel driving circuit CCPa. The first lower electrode BE1 may be attached to the first reflective layer RFL1 and the first connection electrode CE1 through the first adhesive pattern ADP1.

The first lower electrode BE1 may be electrically connected to the first pixel driving circuit CCPa. In one or more embodiments, the first lower electrode BE1 may be electrically connected to a first lower semiconductor layer PS1. For example, the first lower electrode BE1 may be referred to as a p-type electrode. The first lower electrode BE1 may include a conductive material such as a metal, an alloy, a conductive metal nitride, a conductive metal oxide, a transparent conductive oxide, and/or the like. In one or more embodiments, the first lower electrode BE1 may include a transparent conductive oxide. For example, the first lower electrode BE1 may include indium tin oxide (ITO), but the present disclosure is not limited thereto. For example, the first lower electrode BE1 may serve as an anode electrode. For example, the first lower electrode BE1 may have a tapered shape in a cross-section. However, the shape of the first lower electrode BE1 is not limited thereto.

The first light-emitting element LD1 may be on the first lower electrode BE1. For example, the first light-emitting element LD1 may generate green light, but the present disclosure is not limited thereto. In one or more embodiments, the first light-emitting element LD1 may be a micro light-emitting diode. As illustrated in FIG. 4, the first light-emitting element LD1 may include the first lower semiconductor layer PS1, a first active layer MQW1, and a first upper semiconductor layer NS1.

The first lower semiconductor layer PS1 may be on the first lower electrode BE1. The first lower semiconductor layer PS1 may include a p-type semiconductor. For example, the first lower semiconductor layer PS1 may include p-type doped AlGaInN, GaN, AlGaN, InGaN, AlN, InN, and/or the like. These may be used alone or in combination with each other. The first lower semiconductor layer PS1 may be doped with a p-type dopant. The p-type dopant may include magnesium (Mg), zinc (Zn), calcium (Ca), selenium (Se), barium (Ba), and/or the like. For example, the first lower semiconductor layer PS1 may include p-GaN doped with p-type Mg.

The first active layer MQW1 may be on the first lower semiconductor layer PS1. The first active layer MQW1 may generate light by the coupling of electron-hole pairs according to an electric signal applied through the first lower semiconductor layer PS1 and the first upper semiconductor layer NS1.

The first active layer MQW1 may include a material having a single or multiple quantum well structure. For example, when the first active layer MQW1 includes a material having a multiple quantum well structure, the first active layer MQW1 may have a structure in which well layers and barrier layers are alternately stacked. The well layer may include InGaN, and the barrier layer may include GaN and/or AlGaN. However, the present disclosure is not limited thereto.

The first active layer MQW1 may include different group III to group V semiconductor materials depending on the wavelength of light to be emitted. For example, when the semiconductor materials included in the first active layer MQW1 include indium (In), the color of emitted light may vary depending on the content (e.g., amount) of indium (In). When the content (e.g., amount) of indium (In) decreases, the wavelength band of emitted light may shift to a red wavelength band, and when the content (e.g., amount) of indium (In) increases, the wavelength band of emitted light may shift to a blue wavelength band. For example, the first active layer MQW1 may be to emit green light.

The first upper semiconductor layer NS1 may be on the first active layer MQW1. The first upper semiconductor layer NS1 may include an n-type semiconductor. For example, the first upper semiconductor layer NS1 may include n-type doped AlGaInN, GaN, AlGaN, InGaN, AlN, InN, and/or the like. These may be used alone or in combination with each other. The first upper semiconductor layer NS1 may be doped with an n-type dopant. The n-type dopant may include silicon (Si), germanium (Ge), tin (Sn), and/or the like. For example, the first upper semiconductor layer NS1 may include n-GaN doped with n-type Si.

For example, each of the first lower semiconductor layer PS1, the first active layer MQW1, and the first upper semiconductor layer NS1 may have a tapered shape in a cross-section. However, the shape of each of the first lower semiconductor layer PS1, the first active layer MQW1, and the first upper semiconductor layer NS1 is not limited thereto.

The first upper electrode UE1 may be on the first upper semiconductor layer NS1. The first upper electrode UE1 may be electrically connected to the first common voltage line CVL1. Accordingly, the first upper electrode UE1 may receive a common voltage through the first common voltage line CVL1. In one or more embodiments, the first upper electrode UE1 may be electrically connected to the first upper semiconductor layer NS1. For example, the first upper electrode UE1 may be referred to as an n-type electrode. The first upper electrode UE1 may include a conductive material, such as a metal, an alloy, a conductive metal nitride, a conductive metal oxide, a transparent conductive oxide, and/or the like. In one or more embodiments, the first upper electrode UE1 may include a transparent conductive oxide. For example, the first upper electrode UE1 may include indium tin oxide (ITO), but the present disclosure is not limited thereto. For example, the first upper electrode UE1 may serve as a cathode electrode. For example, the first upper electrode UE1 may have a tapered shape in a cross-section. However, the shape of the first upper electrode UE1 is not limited thereto.

As illustrated in FIG. 3, the first dummy lower electrode DBE1, the first dummy light-emitting element DLD1, and the first dummy upper electrode DUE1 may be provided in the dummy pixel area DUMA on the first adhesive layer ADL1. The first dummy lower electrode DBE1 may have substantially the same shape as the first lower electrode BE1, and may be formed through substantially the same process as the first lower electrode BE1. The first dummy light-emitting element DLD1 may have substantially the same shape as the first light-emitting element LD1, and may be formed through substantially the same process as the first light-emitting element LD1. Unlike the first light-emitting element LD1, the first dummy light-emitting element DLD1 may not generate light. The first dummy upper electrode DUE1 may have substantially the same shape as the first upper electrode UE1, and may be formed through substantially the same process as the first upper electrode UE1.

The third insulating layer IL3 may be on the first reflective layer RFL1. The third insulating layer IL3 may cover the first lower electrode BE1, the first light-emitting element LD1, the first upper electrode UE1, the first dummy lower electrode DBE1, the first dummy light-emitting element DLD1, and the first dummy upper electrode DUE1. The third insulating layer IL3 may include an inorganic insulating material and/or an organic insulating material.

The second connection electrode CE2 may be provided in the display area DA on the first adhesive pattern ADP1. For example, the second connection electrode CE2 may be provided at an upper surface of the first adhesive pattern ADP1 on which the first light-emitting element LD1 is not formed. The second connection electrode CE2 may be provided in a first lower contact hole that penetrates the third insulating layer IL3 in the display area DA. The second connection electrode CE2 may contact the first adhesive pattern ADP1. Accordingly, the second connection electrode CE2 may be electrically connected to the second pixel driving circuit CCPb and/or the third pixel driving circuit CCPc. The second connection electrode CE2 may include a conductive material such as a metal, an alloy, a conductive metal nitride, a conductive metal oxide, a transparent conductive oxide, and/or the like. In one or more embodiments, the second connection electrode CE2 may include copper (Cu), titanium (Ti), titanium nitride (TiN), and/or tungsten (W), but the present disclosure is not limited thereto.

The second dummy connection electrode DCE2 may be provided in the dummy pixel area DUMA on the first adhesive layer ADL1. The second dummy connection electrode DCE2 may be provided in a first lower dummy contact hole that penetrates the third insulating layer IL3 in the dummy pixel area DUMA. The second dummy connection electrode DCE2 may contact the first adhesive layer ADL1. In one or more embodiments, the second dummy connection electrode DCE2 may include the same material as the second connection electrode CE2, and may be formed through substantially the same process as the second connection electrode CE2.

The first reflective bulkhead RFB1 may be provided in the display area DA on the reflective electrode RFE. The first reflective bulkhead RFB1 may be spaced apart from the first light-emitting element LD1, and may be provided at opposite sides of the first light-emitting element LD1 (e.g., along the second direction DR2). For example, the first reflective bulkhead RFB1 may have a grid shape and/or a matrix shape in a plan view.

The first reflective bulkhead RFB1 may be spaced apart from the first adhesive patterns ADP1. In one or more embodiments, the first reflective bulkhead RFB1 may be between the first adhesive patterns ADP1 in a plan view. For example, the first reflective bulkhead RFB1 may overlap a spaced area between the first adhesive patterns ADP1 in a plan view.

In one or more embodiments, the first reflective bulkhead RFB1 may be between adjacent light-emitting elements in a plan view. For example, the first reflective bulkhead RFB1 may be between the first light-emitting element LD1 and the second light-emitting element LD2, between the second light-emitting element LD2 and the third light-emitting element LD3, and between the first light-emitting element LD1 and the third light-emitting element LD3 in a plan view.

In one or more embodiments, the first reflective bulkhead RFB1 may include a metal with suitably high light reflectance. For example, the first reflective bulkhead RFB1 may include aluminum (Al) and/or silver (Ag), but the present disclosure is not limited thereto. In one or more embodiments, the first reflective bulkhead RFB1 may include scattering particles and a photosensitive polymer in which the scattering particles are dispersed.

The first reflective bulkhead RFB1 may reflect and/or scatter light incident from the first light-emitting element LD1 toward the first reflective bulkhead RFB1. Accordingly, the first reflective bulkhead RFB1 may reflect the light emitted toward the first reflective bulkhead RFB1 in a desired or suitable direction (e.g., the front direction of the display device DD), and the light efficiency of the first light-emitting element LD1 may be improved.

In one or more embodiments, the first reflective bulkhead RFB1 may contact the reflective electrode RFE. For example, the reflective electrode RFE may be electrically connected to the first common voltage line CVL1 through the first reflective bulkhead RFB1. In this case, the first reflective bulkhead RFB1 may be provided in a second lower contact hole that penetrates the second insulating layer IL2, the first reflective layer RFL1, and the third insulating layer IL3 in the display area DA. However, the present disclosure is not limited thereto.

In one or more embodiments, the first reflective bulkhead RFB1 may be spaced apart from the reflective electrode RFE. For example, the reflective electrode RFE may be electrically independent from the first common voltage line CVL1. In this case, the first reflective bulkhead RFB1 may be provided in a second lower contact hole that penetrates the third insulating layer IL3 in the display area DA. For example, the first reflective bulkhead RFB1 may not penetrate the first reflective layer RFL1 and the second insulating layer IL2.

The first dummy reflective bulkhead DRB1 may be provided in the dummy pixel area DUMA on the first adhesive layer ADL1. The first dummy reflective bulkhead DRB1 may be provided in a second lower dummy contact hole that penetrates the third insulating layer IL3 in the dummy pixel area DUMA. In one or more embodiments, the first dummy reflective bulkhead DRB1 may include the same material as the first reflective bulkhead RFB1 and may be formed through substantially the same process as the first reflective bulkhead RFB1.

The first common voltage line CVL1 may be on the first upper electrode UE1 and the first dummy upper electrode DUE1. The first common voltage line CVL1 may be connected to the first upper electrode UE1 and the first dummy upper electrode DUE1 through an opening defined in the third insulating layer IL3. In FIG. 3, the first common voltage line CVL1 connected to the first upper electrode UE1 and the first common voltage line CVL1 connected to the first dummy upper electrode DUE1 are illustrated as being separated (e.g., disconnected) from each other in a cross-section, but the first common voltage line CVL1 connected to the first upper electrode UE1 and the first common voltage line CVL1 connected to the first dummy upper electrode DUE1 may be connected (physically and/or electrically) to each other in a plan view.

The first connection pattern CNP1 and the first dummy connection pattern DCP1 may be on the third insulating layer IL3. The first connection pattern CNP1 may be provided in the display area DA, and the first dummy connection pattern DCP1 may be provided in the dummy pixel area DUMA. The first connection pattern CNP1 and the first dummy connection pattern DCP1 may be formed through substantially the same process as the first common voltage line CVL1. The first connection pattern CNP1 and the first dummy connection pattern DCP1 may be spaced apart from the first common voltage line CVL1. For example, the first connection pattern CNP1 and the first dummy connection pattern DCP1 may be electrically independent from the first common voltage line CVL1.

The fourth insulating layer IL4 may be on the third insulating layer IL3. The fourth insulating layer IL4 may cover the first common voltage line CVL1, the first connection pattern CNP1, and the first dummy connection pattern DCP1. The fourth insulating layer IL4 may include an inorganic insulating material and/or an organic insulating material.

The second reflective layer RFL2 may be between the first light-emitting element LD1 and the second light-emitting element LD2. For example, the second reflective layer RFL2 may be on the fourth insulating layer IL4. In one or more embodiments, the second reflective layer RFL2 may be under the second light-emitting element LD2. In one or more embodiments, the second reflective layer RFL2 may be provided in only a portion of the display area DA. In this case, the second reflective layer RFL2 may overlap the second light-emitting element LD2 in a plan view, and may not overlap the first light-emitting element LD1 and the third light-emitting element LD3 in a plan view. In one or more embodiments, the second reflective layer RFL2 may also be under the second dummy light-emitting element DLD2. For example, the second reflective layer RFL2 may also be provided in a portion of the dummy pixel area DUMA. However, the present disclosure is not limited thereto, and the second reflective layer RFL2 may not be arranged in the dummy pixel area DUMA.

For example, the second reflective layer RFL2 may include a distributed Bragg reflective layer in which the first sub-layer (SUL1, refer to FIG. 4) having the first refractive index and the second sub-layer (SUL2, refer to FIG. 4) having the second refractive index are alternately and repeatedly stacked. For example, the second reflective layer RFL2 may include at least one middle sub-insulating layer in which the first sub-layer SUL1 and the second sub-layer SUL2 having different refractive indices are sequentially stacked. However, the present disclosure is not limited thereto, and the middle sub-insulating layer may have a structure in which three or more sub-layers having different refractive indices are stacked.

By controlling the component material, the thickness, and/or the number of layers of the first sub-layer SUL1 and the second sub-layer SUL2, the reflectivity of light incident on the second reflective layer RFL2 may be improved. For example, the thickness and/or the number of layers of the first sub-layer SUL1 and the second sub-layer SUL2 may be determined in consideration of a wavelength of light (e.g., blue light) to be emitted by the second light-emitting element LD2. Accordingly, the second reflective layer RFL2 may reflect light emitted toward the second reflective layer RFL2 by the second light-emitting element LD2 in a desired or suitable direction, and the light efficiency of the second light-emitting element LD2 may be improved.

The fifth insulating layer IL5 may be on the fourth insulating layer IL4. The fifth insulating layer IL5 may cover the second reflective layer RFL2. The fifth insulating layer IL5 may include an inorganic insulating material and/or an organic insulating material.

The third connection electrode CE3 may be provided in the display area DA on the first connection pattern CNP1. The third connection electrode CE3 may be provided in a second through hole that penetrates the fourth insulating layer IL4, the second reflective layer RFL2, and the fifth insulating layer IL5 in the display area DA. The third connection electrode CE3 may contact the first connection pattern CNP1 electrically connected to the second pixel driving circuit CCPb. Accordingly, the third connection electrode CE3 may be electrically connected to the second pixel driving circuit CCPb. The third connection electrode CE3 may include a conductive material such as a metal, an alloy, a conductive metal nitride, a conductive metal oxide, a transparent conductive oxide, and/or the like. In one or more embodiments, the third connection electrode CE3 may include copper (Cu), titanium (Ti), titanium nitride (TiN), and/or tungsten (W), but the present disclosure is not limited thereto.

The third dummy connection electrode DCE3 may be provided in the dummy pixel area DUMA on the first dummy connection pattern DCP1. The third dummy connection electrode DCE3 may be provided in a second dummy through hole that penetrates the fourth insulating layer IL4, the second reflective layer RFL2, and the fifth insulating layer IL5 in the dummy pixel area DUMA. The third dummy connection electrode DCE3 may contact the first dummy connection pattern DCP1. In one or more embodiments, the third dummy connection electrode DCE3 may include the same material as the third connection electrode CE3, and may be formed through substantially the same process as the third connection electrode CE3.

The second adhesive pattern ADP2 may be on the fifth insulating layer IL5. The second adhesive pattern ADP2 may be provided in the display area DA and the dummy pixel area DUMA. The second adhesive pattern ADP2 may include a conductive material, such as a metal, an alloy, and/or the like. For example, the second adhesive pattern ADP2 may include gold (Au), tin (Sn), silver (Ag), aluminum (Al), titanium (Ti), and/or the like. In one or more embodiments, the second adhesive pattern ADP2 may include a tin (Sn)-gold (Au) alloy, but the present disclosure is not limited thereto. The second adhesive pattern ADP2 provided in the display area DA may contact the third connection electrode CE3. The second adhesive pattern ADP2 provided in the dummy pixel area DUMA may contact the third dummy connection electrode DCE3. The second adhesive pattern ADP2 may be spaced apart from the second reflective bulkhead RFB2.

The second lower electrode BE2, the second light-emitting element LD2, and the second upper electrode UE2 may have substantially the same or similar (e.g., symmetrical) shapes as the first lower electrode BE1, the first light-emitting element LD1, and the first upper electrode UE1, respectively. Hereinafter, redundant descriptions of the first lower electrode BE1, the first light-emitting element LD1, and the first upper electrode UE1 may not be provided or may be summarized.

The second lower electrode BE2 may be on the second adhesive pattern ADP2. For example, the second lower electrode BE2 may be provided at an upper surface of the second adhesive pattern ADP2 that is electrically connected to the second pixel driving circuit CCPb. The second lower electrode BE2 may be attached to the fifth insulating layer IL5 and the third connection electrode CE3 through the second adhesive pattern ADP2.

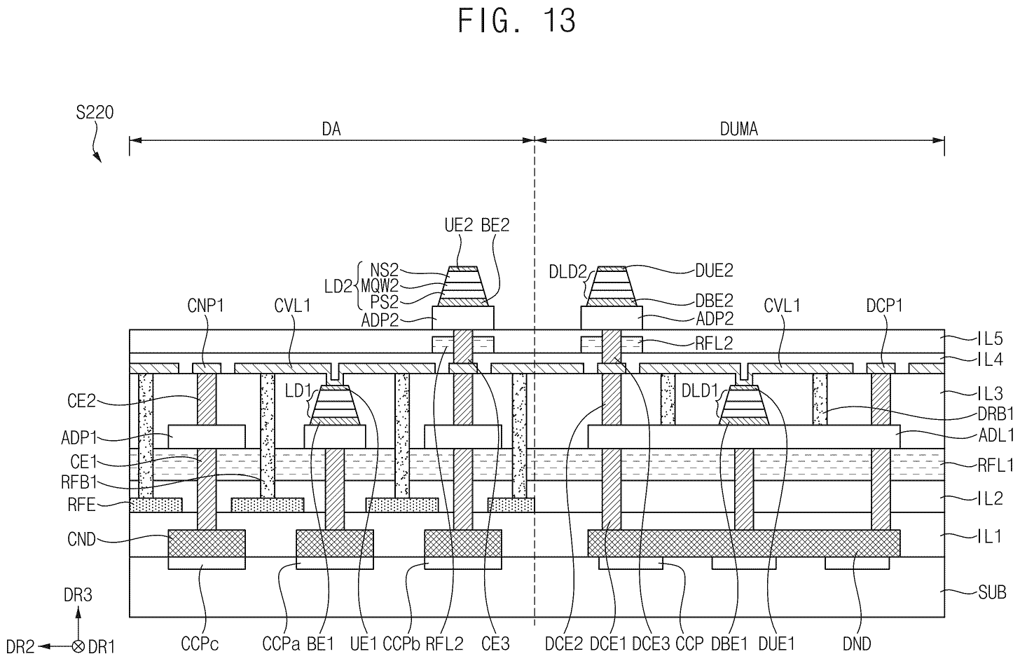

The second lower electrode BE2 may be electrically connected to the second pixel driving circuit CCPb. In one or more embodiments, the second lower electrode BE2 may be electrically connected to a second lower semiconductor layer (PS2, refer to FIG. 13). For example, the second lower electrode BE2 may be referred to as a p-type electrode.

The second light-emitting element LD2 may be on the second lower electrode BE2. The first light-emitting element LD1 and the second light-emitting element LD2 may be to emit light of different colors. For example, the second light-emitting element LD2 may generate blue light, but the present disclosure is not limited thereto. In one or more embodiments, the second light-emitting element LD2 may be a micro light-emitting diode. The second light-emitting element LD2 may include the second lower semiconductor layer (PS2, refer to FIG. 13), a second active layer (MQW2, refer to FIG. 13), and a second upper semiconductor layer (NS2, refer to FIG. 13).

The second lower semiconductor layer PS2 may be on the second lower electrode BE2. The second lower semiconductor layer PS2 may include a p-type semiconductor. The second lower semiconductor layer PS2 may be doped with a p-type dopant.

The second active layer MQW2 may be on the second lower semiconductor layer PS2. The second active layer MQW2 may include a material having a single or multiple quantum well structure. The second active layer MQW2 may include different group III to group V semiconductor materials depending on the wavelength of light to be emitted. For example, the second active layer MQW2 may be to emit blue light.

The second upper semiconductor layer NS2 may be on the second active layer MQW2. The second upper semiconductor layer NS2 may include an n-type semiconductor. The second upper semiconductor layer NS2 may be doped with an n-type dopant.

The second upper electrode UE2 may be on the second upper semiconductor layer NS2. The second upper electrode UE2 may be electrically connected to the second common voltage line CVL2. Accordingly, the second upper electrode UE2 may receive the common voltage through the second common voltage line CVL2. In one or more embodiments, the second upper electrode UE2 may be electrically connected to the second upper semiconductor layer NS2. For example, the second upper electrode UE2 may be referred to as an n-type electrode.

The second dummy lower electrode DBE2, the second dummy light-emitting element DLD2, and the second dummy upper electrode DUE2 may be provided in the dummy pixel area DUMA on the second adhesive pattern ADP2. The second dummy lower electrode DBE2 may have substantially the same shape as the second lower electrode BE2, and may be formed through substantially the same process as the second lower electrode BE2. The second dummy light-emitting element DLD2 may have substantially the same shape as the second light-emitting element LD2, and may be formed through substantially the same process as the second light-emitting element LD2. Unlike the second light-emitting element LD2, the second dummy light-emitting element DLD2 may not generate light. The second dummy upper electrode DUE2 may have substantially the same shape as the second upper electrode UE2, and may be formed through substantially the same process as the second upper electrode UE2.

The sixth insulating layer IL6 may be on the fifth insulating layer IL5. The sixth insulating layer IL6 may cover the second adhesive pattern ADP2, the second lower electrode BE2, the second light-emitting element LD2, the second upper electrode UE2, the second dummy lower electrode DBE2, the second dummy light-emitting element DLD2, and the second dummy upper electrode DUE2. The sixth insulating layer IL6 may include an inorganic insulating material and/or an organic insulating material.

The fourth connection electrode CE4 may be provided in the display area DA on the first connection pattern CNP1. For example, the fourth connection electrode CE4 may be provided at an upper surface of the first connection pattern CNP1 that does not overlap the second light-emitting element LD2 in a plan view. The fourth connection electrode CE4 may be provided in a first middle contact hole that penetrates the fourth insulating layer IL4, the fifth insulating layer IL5, and the sixth insulating layer IL6 in the display area DA. The fourth connection electrode CE4 may be electrically connected to the third pixel driving circuit CCPc through the first connection pattern CNP1. The fourth connection electrode CE4 may include a conductive material such as a metal, an alloy, a conductive metal nitride, a conductive metal oxide, a transparent conductive oxide, and/or the like. In one or more embodiments, the fourth connection electrode CE4 may include copper (Cu), titanium (Ti), titanium nitride (TiN), and/or tungsten (W), but the present disclosure is not limited thereto.

The fourth dummy connection electrode DCE4 may be provided in the dummy pixel area DUMA on the first dummy connection pattern DCP1. The fourth dummy connection electrode DCE4 may be provided in a first middle dummy contact hole that penetrates the fourth insulating layer IL4, the fifth insulating layer IL5, and the sixth insulating layer IL6 in the dummy pixel area DUMA. The fourth dummy connection electrode DCE4 may contact the first dummy connection pattern DCP1. In one or more embodiments, the fourth dummy connection electrode DCE4 may include the same material as the fourth connection electrode CE4, and may be formed through substantially the same process as the fourth connection electrode CE4.

The second reflective bulkhead RFB2 may be provided in the display area DA on the first common voltage line CVL1. The second reflective bulkhead RFB2 may be spaced apart from the second light-emitting element LD2, and may be provided at opposite sides of the second light-emitting element LD2 (e.g., along the second direction DR2). For example, the second reflective bulkhead RFB2 may have a grid shape and/or a matrix shape in a plan view. The second reflective bulkhead RFB2 may be spaced apart from the second adhesive pattern ADP2.

The second reflective bulkhead RFB2 may be provided in a second middle contact hole that penetrates the fourth insulating layer IL4, the fifth insulating layer IL5, and the sixth insulating layer IL6 in the display area DA. In one or more embodiments, the second reflective bulkhead RFB2 may be between adjacent light-emitting elements in a plan view. For example, the second reflective bulkhead RFB2 may be between the first light-emitting element LD1 and the second light-emitting element LD2, between the second light-emitting element LD2 and the third light-emitting element LD3, and between the first light-emitting element LD1 and the third light-emitting element LD3 in a plan view.

The second reflective bulkhead RFB2 may be positioned at (e.g., along) the same line as the first reflective bulkhead RFB1 in a cross-section. For example, the second reflective bulkhead RFB2 may be positioned at the same line extending in the third direction DR3 as the first reflective bulkhead RFB1.

In one or more embodiments, the second reflective bulkhead RFB2 may include a metal with suitably high light reflectance. For example, the second reflective bulkhead RFB2 may include aluminum (Al) and/or silver (Ag), but the present disclosure is not limited thereto. In one or more embodiments, the second reflective bulkhead RFB2 may include scattering particles and a photosensitive polymer in which the scattering particles are dispersed.

The second reflective bulkhead RFB2 may reflect and/or scatter light incident from the second light-emitting element LD2 toward the second reflective bulkhead RFB2. Accordingly, the second reflective bulkhead RFB2 may reflect light emitted toward the second reflective bulkhead RFB2 in a desired or suitable direction, and the light efficiency of the second light-emitting element LD2 may be improved.

The second dummy reflective bulkhead DRB2 may be provided in the dummy pixel area DUMA on the first common voltage line CVL1. The second dummy reflective bulkhead DRB2 may be provided in a second middle dummy contact hole that penetrates the fourth insulating layer IL4, the fifth insulating layer IL5, and the sixth insulating layer IL6 in the dummy pixel area DUMA. In one or more embodiments, the second dummy reflective bulkhead DRB2 may include the same material as the second reflective bulkhead RFB2 and may be formed through substantially the same process as the second reflective bulkhead RFB2.

The second common voltage line CVL2 may be on the second upper electrode UE2 and the second dummy upper electrode DUE2. The second common voltage line CVL2 may be connected to the second upper electrode UE2 and the second dummy upper electrode DUE2 through an opening defined in the sixth insulating layer IL6.

The second connection pattern CNP2 and the second dummy connection pattern DCP2 may be on the sixth insulating layer IL6. The second connection pattern CNP2 may be provided in the display area DA, and the second dummy connection pattern DCP2 may be provided in the dummy pixel area DUMA. The second connection pattern CNP2 and the second dummy connection pattern DCP2 may be formed through substantially the same process as the second common voltage line CVL2. The second connection pattern CNP2 and the second dummy connection pattern DCP2 may be spaced apart from the second common voltage line CVL2. For example, the second connection pattern CNP2 and the second dummy connection pattern DCP2 may be electrically independent from the second common voltage line CVL2.

The seventh insulating layer IL7 may be on the sixth insulating layer IL6. The seventh insulating layer IL7 may cover the second common voltage line CVL2, the second connection pattern CNP2, and the second dummy connection pattern DCP2. The seventh insulating layer IL7 may include an inorganic insulating material and/or an organic insulating material.

The third reflective layer RFL3 may be between the second light-emitting element LD2 and the third light-emitting element LD3. For example, the third reflective layer RFL3 may be on the seventh insulating layer IL7. In one or more embodiments, the third reflective layer RFL3 may be under the third light-emitting element LD3. In one or more embodiments, the third reflective layer RFL3 may be provided in only a portion of the display area DA. In this case, the third reflective layer RFL3 may overlap the third light-emitting element LD3 in a plan view, and may not overlap the first light-emitting element LD1 and the second light-emitting element LD2 in a plan view. In one or more embodiments, the third reflective layer RFL3 may be under the third dummy light-emitting element DLD3. For example, the third reflective layer RFL3 may also be provided in a portion of the dummy pixel area DUMA. However, the present disclosure is not limited thereto, and the third reflective layer RFL3 may not be provided in the dummy pixel area DUMA.

For example, the third reflective layer RFL3 may include a distributed Bragg reflective layer in which the first sub-layer (SUL1, refer to FIG. 4) having the first refractive index and the second sub-layer (SUL2, refer to FIG. 4) having the second refractive index are alternately and repeatedly stacked. For example, the third reflective layer RFL3 may include at least one upper sub-insulating layer in which the first sub-layer SUL1 and the second sub-layer SUL2 having different refractive indices are sequentially stacked. However, the present disclosure is not limited thereto, and the upper sub-insulating layer may have a structure in which three or more sub-layers having different refractive indices are stacked.

By controlling the component material, the thickness, and/or the number of layers of the first sub-layer SUL1 and the second sub-layer SUL2, the reflectivity of light incident on the third reflective layer RFL3 may be improved. For example, the thickness and/or the number of layers of the first sub-layer SUL1 and the second sub-layer SUL2 may be determined in consideration of a wavelength of light (e.g., red light) emitted by the third light-emitting element LD3. Accordingly, the third reflective layer RFL3 may reflect light emitted toward the third reflective layer RFL3 by the third light-emitting element LD3 in a desired or suitable direction, and the light efficiency of the third light-emitting element LD3 may be improved.

The eighth insulating layer IL8 may be on the seventh insulating layer IL7. The eighth insulating layer IL8 may cover the third reflective layer RFL3. The eighth insulating layer IL8 may include an inorganic insulating material and/or an organic insulating material.

The fifth connection electrode CE5 may be provided in the display area DA on the second connection pattern CNP2. The fifth connection electrode CE5 may be provided in a third through hole that penetrates the seventh insulating layer IL7, the third reflective layer RFL3, and the eighth insulating layer IL8 in the display area DA. The fifth connection electrode CE5 may contact the second connection pattern CNP2 that is electrically connected to the third pixel driving circuit CCPc. Accordingly, the fifth connection electrode CE5 may be electrically connected to the third pixel driving circuit CCPc. The fifth connection electrode CE5 may include a conductive material such as a metal, an alloy, a conductive metal nitride, a conductive metal oxide, a transparent conductive oxide, and/or the like. In one or more embodiments, the fifth connection electrode CE5 may include copper (Cu), titanium (Ti), titanium nitride (TiN), and/or tungsten (W), but the present disclosure is not limited thereto.

The fifth dummy connection electrode DCE5 may be provided in the dummy pixel area DUMA on the second dummy connection pattern DCP2. The fifth dummy connection electrode DCE5 may be provided in a third dummy through hole that penetrates the seventh insulating layer IL7, the third reflective layer RFL3, and the eighth insulating layer IL8 in the dummy pixel area DUMA. The fifth dummy connection electrode DCE5 may contact the second dummy connection pattern DCP2. In one or more embodiments, the fifth dummy connection electrode DCE5 may include the same material as the fifth connection electrode CE5, and may be formed through substantially the same process as the fifth connection electrode CE5.

The third adhesive pattern ADP3 may be on the eighth insulating layer IL8. The third adhesive pattern ADP3 may be provided in the display area DA and the dummy pixel area DUMA. The third adhesive pattern ADP3 may include a conductive material such as a metal, an alloy, and/or the like. For example, the third adhesive pattern ADP3 may include gold (Au), tin (Sn), silver (Ag), aluminum (Al), titanium (Ti), and/or the like. In one or more embodiments, the third adhesive pattern ADP3 may include a tin (Sn)-gold (Au) alloy, but the present disclosure is not limited thereto. The third adhesive pattern ADP3 provided in the display area DA may contact the fifth connection electrode CE5. The third adhesive pattern ADP3 provided in the dummy pixel area DUMA may contact the fifth dummy connection electrode DCE5. The third adhesive pattern ADP3 may be spaced apart from the third reflective bulkhead RFB3.

The third lower electrode BE3, the third light-emitting element LD3, and the third upper electrode UE3 may have substantially the same or similar (e.g., symmetrical) shapes as the first lower electrode BE1, the first light-emitting element LD1, and the first upper electrode UE1, respectively. Hereinafter, redundant descriptions of the first lower electrode BE1, the first light-emitting element LD1, and the first upper electrode UE1 may not be provided or may be summarized.

The third lower electrode BE3 may be on the third adhesive pattern ADP3. For example, the third lower electrode BE3 may be provided at an upper surface of the third adhesive pattern ADP3 that is electrically connected to the third pixel driving circuit CCPc. The third lower electrode BE3 may be attached to the eighth insulating layer IL8 and the fifth connection electrode CE5 through the third adhesive pattern ADP3.

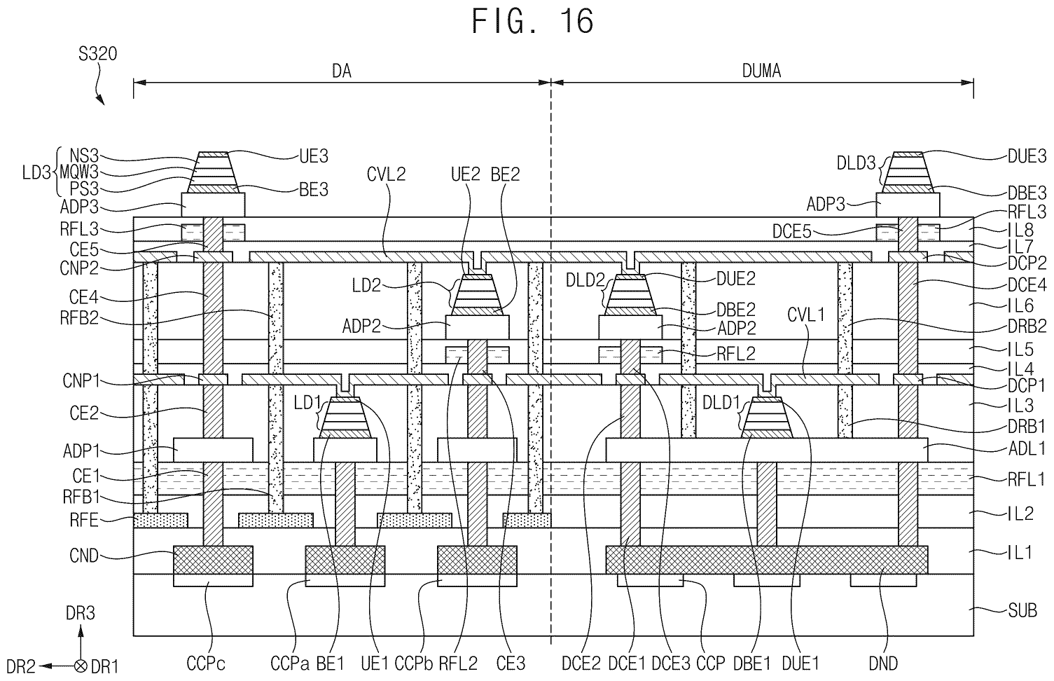

The third lower electrode BE3 may be electrically connected to the third pixel driving circuit CCPc. In one or more embodiments, the third lower electrode BE3 may be electrically connected to a third lower semiconductor layer (PS3, refer to FIG. 16). For example, the third lower electrode BE3 may be referred to as a p-type electrode.

The third light-emitting element LD3 may be on the third lower electrode BE3. The first light-emitting element LD1, the second light-emitting element LD2, and the third light-emitting element LD3 may be to emit light of different colors. For example, the third light-emitting element LD3 may generate red light, but the present disclosure is not limited thereto. In one or more embodiments, the third light-emitting element LD3 may be a micro light-emitting diode. The third light-emitting element LD3 may include the third lower semiconductor layer (PS3, refer to FIG. 16), a third active layer (MQW3, refer to FIG. 16), and a third upper semiconductor layer (NS3, refer to FIG. 16).

The third lower semiconductor layer PS3 may be on the third lower electrode BE3. The third lower semiconductor layer PS3 may include a p-type semiconductor. The third lower semiconductor layer PS3 may be doped with a p-type dopant.

The third active layer MQW3 may be on the third lower semiconductor layer PS3. The third active layer MQW3 may include a material having a single or multiple quantum well structure. The third active layer MQW3 may include different group III to group V semiconductor materials depending on the wavelength of light emitted. For example, the third active layer MQW3 may be to emit red light.

The third upper semiconductor layer NS3 may be on the third active layer MQW3. The third upper semiconductor layer NS3 may include an n-type semiconductor. The third upper semiconductor layer NS3 may be doped with an n-type dopant.

The third upper electrode UE3 may be on the third upper semiconductor layer NS3. The third upper electrode UE3 may be electrically connected to the third common voltage line CVL3. Accordingly, the third upper electrode UE3 may receive the common voltage through the third common voltage line CVL3. In one or more embodiments, the third upper electrode UE3 may be electrically connected to the third upper semiconductor layer. For example, the third upper electrode UE3 may be referred to as an n-type electrode.

The third dummy lower electrode DBE3, the third dummy light-emitting element DLD3, and the third dummy upper electrode DUE3 may be provided in the dummy pixel area DUMA on the third adhesive pattern ADP3. The third dummy lower electrode DBE3 may have substantially the same shape as the third lower electrode BE3, and may be formed through substantially the same process as the third lower electrode BE3. The third dummy light-emitting element DLD3 may have substantially the same shape as the third light-emitting element LD3, and may be formed through substantially the same process as the third light-emitting element LD3. Unlike the third light-emitting element LD3, the third dummy light-emitting element DLD3 may not generate light. The third dummy upper electrode DUE3 may have substantially the same shape as the third upper electrode UE3, and may be formed through substantially the same process as the third upper electrode UE3.

The ninth insulating layer IL9 may be on the eighth insulating layer IL8. The ninth insulating layer IL9 may cover the third adhesive pattern ADP3, the third lower electrode BE3, the third light-emitting element LD3, the third upper electrode UE3, the third dummy lower electrode DBE3, the third dummy light-emitting element DLD3, and the third dummy upper electrode DUE3. The ninth insulating layer IL9 may include an inorganic insulating material and/or an organic insulating material.

The third reflective bulkhead RFB3 may be provided in the display area DA on the second common voltage line CVL2. The third reflective bulkhead RFB3 may be spaced apart from the third light-emitting element LD3, and may be provided at opposite sides of the third light-emitting element LD3 (e.g., along the second direction DR2). For example, the third reflective bulkhead RFB3 may have a grid shape and/or a matrix shape in a plan view.

The third reflective bulkhead RFB3 may be provided in an upper contact hole that penetrates the seventh insulating layer IL7, the eighth insulating layer IL8, and the ninth insulating layer IL9 in the display area DA. In one or more embodiments, the third reflective bulkhead RFB3 may be between adjacent light-emitting elements in a plan view. For example, the third reflective bulkhead RFB3 may be between the first light-emitting element LD1 and the second light-emitting element LD2, between the second light-emitting element LD2 and the third light-emitting element LD3, and between the first light-emitting element LD1 and the third light-emitting element LD3 in a plan view.

The third reflective bulkhead RFB3 may be positioned at (e.g., along) the same line as the first reflective bulkhead RFB1 and the second reflective bulkhead RFB2 in a cross-section. For example, the third reflective bulkhead RFB3 may be positioned at the same line extending in the third direction DR3 as the first reflective bulkhead RFB1 and the second reflective bulkhead RFB2.

In one or more embodiments, the third reflective bulkhead RFB3 may include a metal with suitably high light reflectance. For example, the third reflective bulkhead RFB3 may include aluminum (Al) and/or silver (Ag), but the present disclosure is not limited thereto. In one or more embodiments, the third reflective bulkhead RFB3 may include scattering particles and a photosensitive polymer in which the scattering particles are dispersed.

The third reflective bulkhead RFB3 may reflect and/or scatter light incident from the third light-emitting element LD3 toward the third reflective bulkhead RFB3. Accordingly, the third reflective bulkhead RFB3 may reflect light emitted toward the third reflective bulkhead RFB3 in a desired or suitable direction, and the light efficiency of the third light-emitting element LD3 may be improved.

The third dummy reflective bulkhead DRB3 may be provided in the dummy pixel area DUMA on the second common voltage line CVL2. The third dummy reflective bulkhead DRB3 may be provided in an upper dummy contact hole that penetrates the seventh insulating layer IL7, the eighth insulating layer IL8, and the ninth insulating layer IL9 in the dummy pixel area DUMA. In one or more embodiments, the third dummy reflective bulkhead DRB3 may include the same material as the third reflective bulkhead RFB3, and may be formed through substantially the same process as the third reflective bulkhead RFB3.

The third common voltage line CVL3 may be on the third upper electrode UE3 and the third dummy upper electrode DUE3. The third common voltage line CVL3 may be connected to the third upper electrode UE3 and the third dummy upper electrode DUE3 through an opening defined by the ninth insulating layer IL9.

The tenth insulating layer IL10 may be on the ninth insulating layer IL9. The tenth insulating layer IL10 may cover the third common voltage line CVL3. The tenth insulating layer IL10 may include an inorganic insulating material and/or an organic insulating material.

The lens layer LL may be on the third light-emitting element LD3. For example, the lens layer LL may be provided in the display area DA on the tenth insulating layer IL10. The lens layer LL may include micro lenses in the display area DA. The micro lenses may overlap the first light-emitting element LD1, the second light-emitting element LD2, and the third light-emitting element LD3 in a plan view, respectively. The micro lenses may improve light extraction efficiency. The micro lenses may have a refractive index (e.g., a set or predetermined refractive index). For example, the micro lenses may have a refractive index greater than or equal to about 1.5 and less than or equal to about 1.7, but the present disclosure is not limited thereto.

The filling layer OL may be on the lens layer LL. The filling layer OL may be provided in the display area DA and the dummy pixel area DUMA. The filling layer OL may flatten (e.g., substantially planarize) a step difference of (or due to) the lens layer LL. The filling layer OL may include an inorganic insulating material and/or an organic insulating material.

According to one or more embodiments, the reflective electrode RFE may overlap a spaced area between the adhesive pattern and the reflective bulkhead in a plan view. For example, the reflective electrode RFE may overlap a spaced area between the first adhesive pattern ADP1 and the first reflective bulkhead RFB1 in a plan view. In one or more embodiments, the reflective electrode RFE may overlap a spaced area between the second adhesive pattern ADP2 and the second reflective bulkhead RFB2 in a plan view. In one or more embodiments, the reflective electrode RFE may overlap a spaced area between the third adhesive pattern ADP3 and the third reflective bulkhead RFB3 in a plan view. The reflective electrode RFE may reflect light traveling in a spaced space between the adhesive pattern and the reflective bulkhead in a desired or suitable direction (e.g., the front direction of the display device DD). Accordingly, a problem of light loss due to light reflected from the reflective bulkhead traveling to the spaced space between the adhesive pattern and the reflective bulkhead may be effectively prevented or reduced. For example, the light efficiency of the light-emitting element may be improved.

According to one or more embodiments, the reflective layer overlapping the light-emitting element in a plan view may be under the light-emitting element. For example, the first reflective layer RFL1 overlapping the first light-emitting element LD1 in a plan view may be under the first light-emitting element LD1. In one or more embodiments, the second reflective layer RFL2 overlapping the second light-emitting element LD2 in a plan view may be under the second light-emitting element LD2. In one or more embodiments, the third reflective layer RFL3 overlapping the third light-emitting element LD3 in a plan view may be under the third light-emitting element LD3. Each of the first to third reflective layers RFL1, RFL2, and RFL3 may include a distributed Bragg reflective layer in which the first sub-layer SUL1 and the second sub-layer SUL2 having different refractive indices are alternately and repeatedly stacked. Accordingly, the reflective layer may reflect light emitted toward the reflective layer by the light-emitting element in a desired or suitable direction, and the light efficiency of the light-emitting element may be improved.

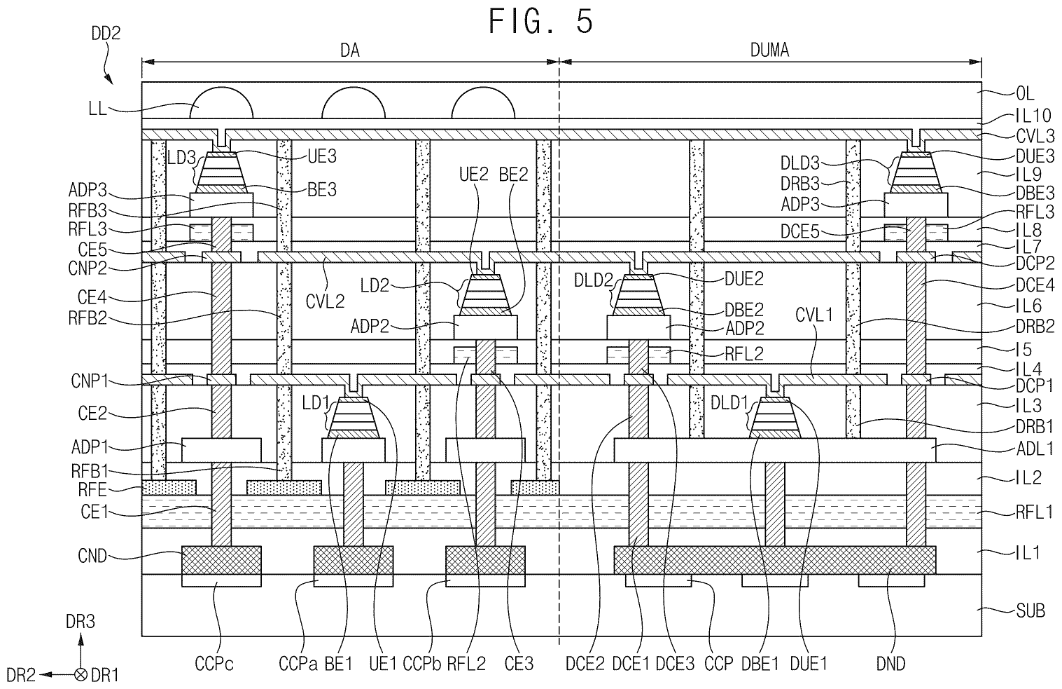

FIG. 5 is a cross-sectional view illustrating a display device according to one or more embodiments of the present disclosure.

A display device DD2 of FIG. 5 may be substantially the same as the display device DD described above with reference to FIGS. 1 to 4, except that a first reflective layer RFL1 is under a reflective electrode RFE. Hereinafter, redundant descriptions of the display device DD described above with reference to FIGS. 1 to 4 may not be provided or may be summarized.

Referring to FIG. 5, the first reflective layer RFL1 may be on the substrate SUB. For example, the first reflective layer RFL1 may be on the first insulating layer IL1. In one or more embodiments, the first reflective layer RFL1 may be under the first light-emitting element LD1. In one or more embodiments, as illustrated in FIG. 5, the first reflective layer RFL1 may be entirely over the display area DA and the dummy pixel area DUMA. In this case, the first reflective layer RFL1 may overlap the first light-emitting element LD1, the second light-emitting element LD2, and the third light-emitting element LD3 in a plan view. However, the present disclosure is not limited thereto.

In one or more embodiments, the first reflective layer RFL1 may be under the first light-emitting element LD1, may overlap the first light-emitting element LD1 in a plan view, and may not overlap the second light-emitting element LD2 and the third light-emitting element LD3 in a plan view. For example, the first reflective layer RFL1 may be provided in only a portion of the display area DA.

In one or more embodiments, the first reflective layer RFL1 may be under the reflective electrode RFE. However, the present disclosure is not limited thereto, and the first reflective layer RFL1 may be provided both (e.g., simultaneously) at a lower portion of the reflective electrode RFE and at an upper portion of the reflective electrode RFE. For example, the first reflective layer RFL1 may include a first lower reflective layer provided at the lower portion of the reflective electrode RFE and a first upper reflective layer provided at the upper portion of the reflective electrode RFE. In this case, the reflective electrode RFE may be surrounded by the first lower reflective layer and the first upper reflective layer.

For example, the first reflective layer RFL1 may include a distributed Bragg reflective layer in which a first sub-layer (SUL1, refer to FIG. 4) having a first refractive index and a second sub-layer (SUL2, refer to FIG. 4) having a second refractive index different from the first refractive index are alternately and repeatedly stacked. For example, the first reflective layer RFL1 may include at least one lower sub-insulating layer in which the first sub-layer and the second sub-layer having different refractive indices are sequentially stacked. The first reflective layer RFL1 may reflect light emitted toward the first reflective layer RFL by the first light-emitting element LD1 in a desired or suitable direction (e.g., a front direction of the display device DD2), and the light efficiency of the first light-emitting element LD1 may be improved.

The reflective electrode RFE may be provided in the display area DA on the first reflective layer RFL1. The reflective electrode RFE may be under the first light-emitting element LD1. The reflective electrode RFE may not be provided in the dummy pixel area DUMA.

The second insulating layer IL2 may be on the first reflective layer RFL1. The second insulating layer IL2 may cover the reflective electrode RFE. The second insulating layer IL2 may include an inorganic insulating material and/or an organic insulating material.

The first reflective bulkhead RFB1 may be provided in the display area DA on the reflective electrode RFE. The first reflective bulkhead RFB1 may be spaced apart from the first light-emitting element LD1, and may be provided at opposite sides of the first light-emitting element LD1.

In one or more embodiments, the first reflective bulkhead RFB1 may be between adjacent light-emitting elements in a plan view. For example, the first reflective bulkhead RFB1 may be between the first light-emitting element LD1 and the second light-emitting element LD2, between the second light-emitting element LD2 and the third light-emitting element LD3, and between the first light-emitting element LD1 and the third light-emitting element LD3 in a plan view.

The first reflective bulkhead RFB1 may reflect and/or scatter light incident from the first light-emitting element LD1 toward the first reflective bulkhead RFB1. Accordingly, the first reflective bulkhead RFB1 may reflect light emitted toward the first reflective bulkhead RFB1 in a desired or suitable direction, and the light efficiency of the first light-emitting element LD1 may be improved.

In one or more embodiments, the first reflective bulkhead RFB1 may contact the reflective electrode RFE. In this case, the first reflective bulkhead RFB1 may penetrate the second insulating layer IL2 and the third insulating layer IL3 in the display area DA. However, the present disclosure is not limited thereto.

In one or more embodiments, the first reflective bulkhead RFB1 may be spaced apart from the reflective electrode RFE. In this case, the first reflective bulkhead RFB1 may penetrate the third insulating layer IL3 in the display area DA. For example, the first reflective bulkhead RFB1 may not penetrate the second insulating layer IL2.

In one or more embodiments, the reflective electrode RFE may overlap a spaced area between the adhesive pattern and the reflective bulkhead in a plan view. For example, the reflective electrode RFE may overlap a spaced area between the first adhesive pattern ADP1 and the first reflective bulkhead RFB1 in a plan view. In one or more embodiments, the reflective electrode RFE may overlap a spaced area between the second adhesive pattern ADP2 and the second reflective bulkhead RFB2 in a plan view. In one or more embodiments, the reflective electrode RFE may overlap a spaced area between the third adhesive pattern ADP3 and the third reflective bulkhead RFB3 in a plan view. The reflective electrode RFE may reflect light traveling in a spaced space (e.g., spaced area) between the adhesive pattern and the reflective bulkhead in a desired or suitable direction. Accordingly, the problem of light loss due to light reflected from the reflective bulkhead traveling to the spaced space between the adhesive pattern and the reflective bulkhead may be effectively or suitably prevented or reduced. For example, the light efficiency of the light-emitting element may be improved.

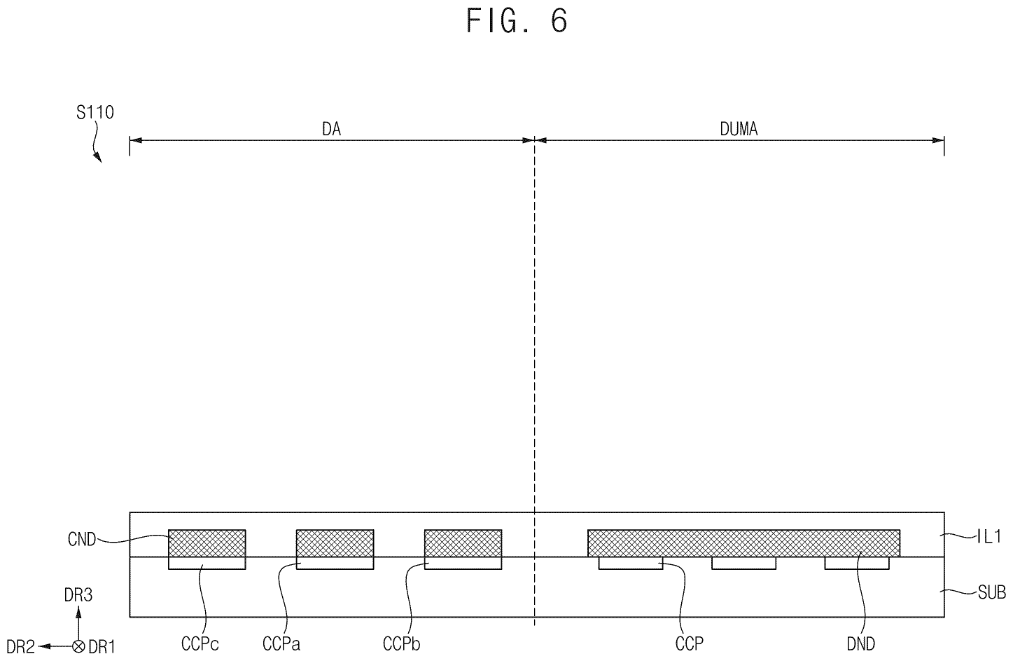

FIGS. 6, 7, 8, 9, 10, 11, 12, 13, 14, 15, 16, 17, and 18 are cross-sectional views illustrating a method of manufacturing a display device according to one or more embodiments of the present disclosure.

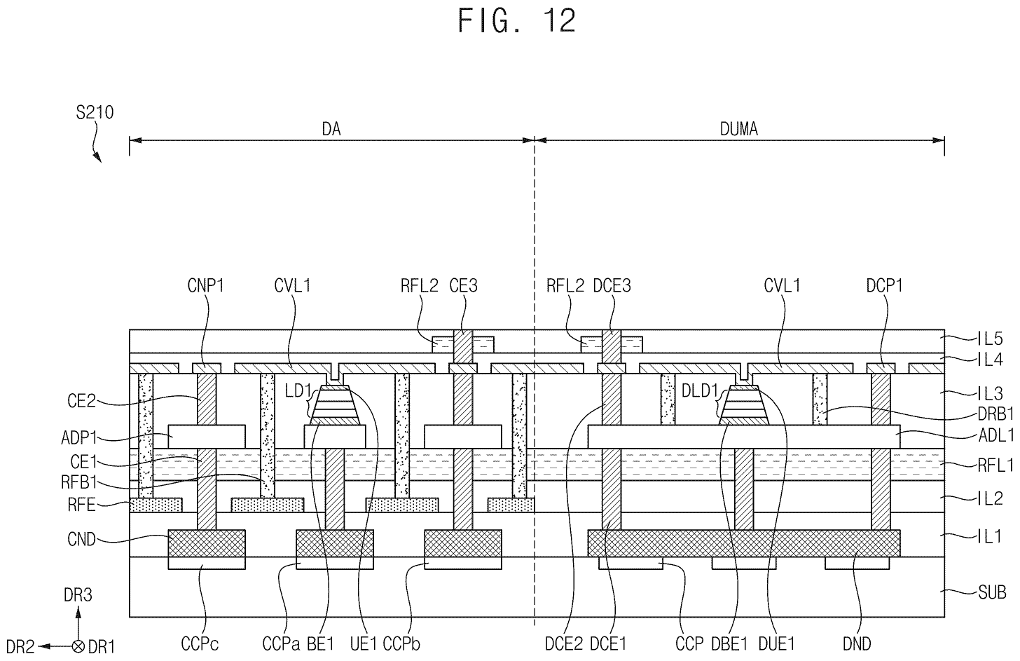

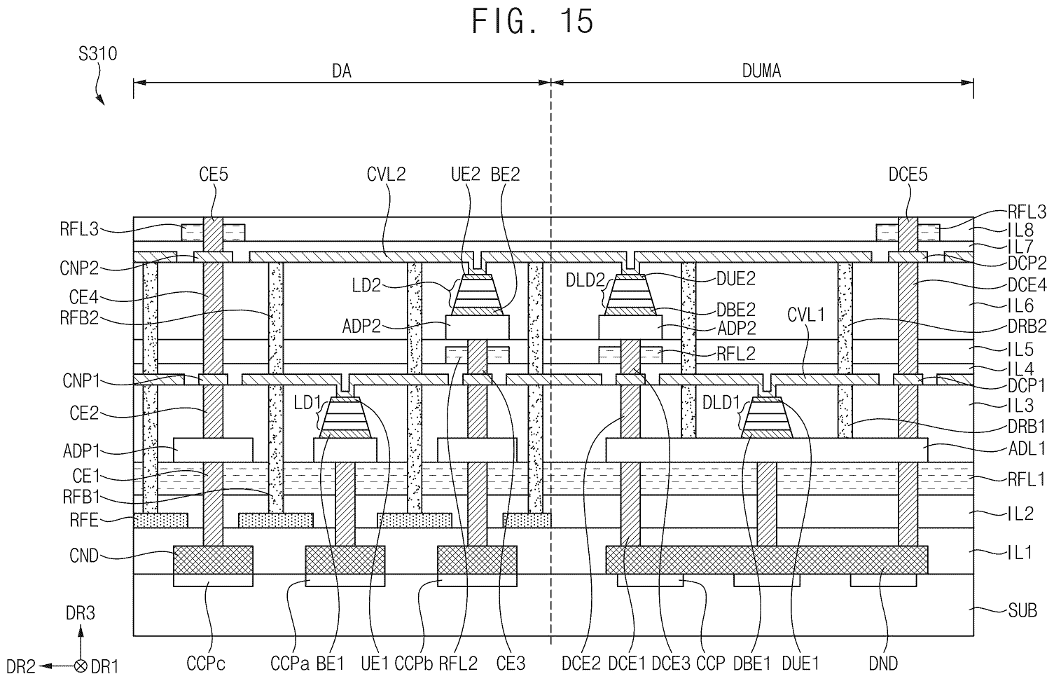

The method of manufacturing the display device described herein below with reference to FIGS. 6 to 18 may be a method of manufacturing the display device DD described above with reference to FIGS. 1 to 4. For example, FIGS. 6 to 11 are cross-sectional views illustrating a method of manufacturing the lower layer including the first light-emitting element LD1 of FIG. 3. In addition, FIGS. 12 to 14 are cross-sectional views illustrating a method of manufacturing the middle layer including the second light-emitting element LD2 of FIG. 3. In addition, FIGS. 15 to 18 are cross-sectional views illustrating a method of manufacturing the upper layer including the third light-emitting element LD3 of FIG. 3. Hereinafter, redundant descriptions of the display device DD described above with reference to FIGS. 1 to 4 may not be provided or may be summarized.

A method of manufacturing the display device DD2 described above with reference to FIG. 5 may be substantially the same as the method of manufacturing the display device DD described above with reference to FIGS. 1 to 4, except that after forming the first reflective layer RFL1, the reflective electrode RFE is formed on the first reflective layer RFL1. Accordingly, the description of the method of manufacturing the display device DD2 described above with reference to FIG. 5 is not provided.

Referring to FIG. 6, the connection pads CND may be formed in the display area DA on the substrate SUB (S110).

In one or more embodiments, the substrate SUB may include silicon (Si). For example, the substrate SUB may be a silicon wafer. However, the present disclosure is not limited thereto, and the substrate SUB may include gallium nitride (GaN), sapphire, gallium arsenide (GaAs), zinc oxide (ZnO), and/or the like. These may be used alone or in combination with each other. The circuit portions CCP may be mounted on the substrate SUB. The circuit portions CCP may include the first to third pixel driving circuits CCPa, CCPb, and CCPc.

The connection pads CND may be formed in the display area DA on the substrate SUB. Each of the connection pads CND may be electrically connected to any one selected from among the first to third pixel driving circuits CCPa, CCPb, and CCPc. The connection pads CND may be spaced apart from each other in the display area DA.

The dummy connection pads DND may be formed in the dummy pixel area DUMA on the substrate SUB. The dummy connection pads DND may be electrically connected to the circuit portions CCP. The dummy connection pads DND may be formed through substantially the same process as the connection pads CND.

The first insulating layer IL1 may be formed on the substrate SUB. The first insulating layer IL1 may be formed (e.g., entirely formed) over the display area DA and the dummy pixel area DUMA. The first insulating layer IL1 may cover the connection pads CND and the dummy connection pads DND.

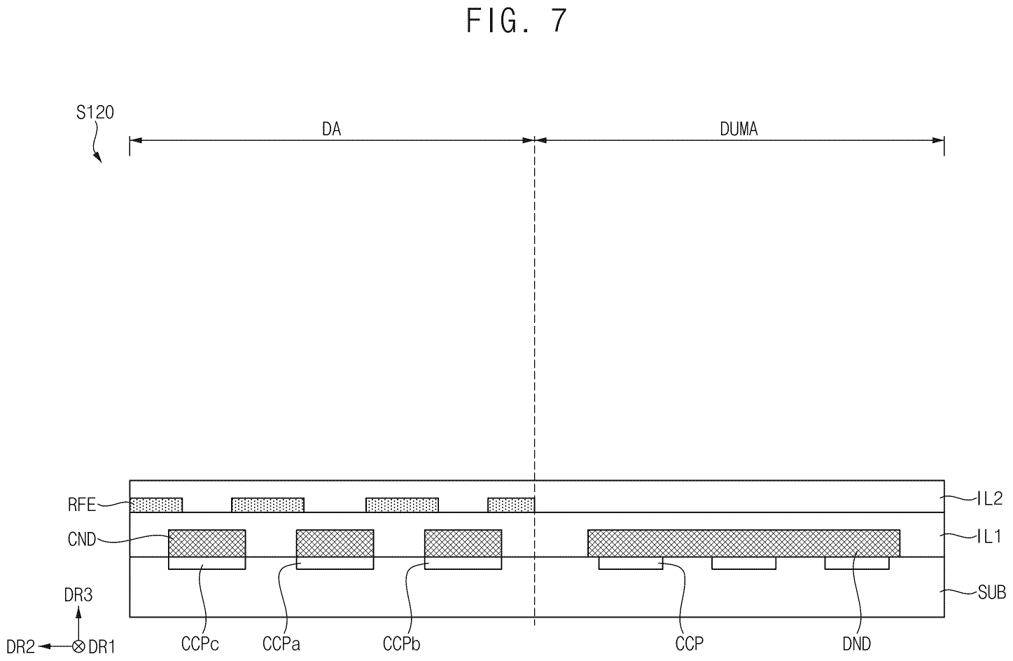

Referring to FIG. 7, the reflective electrodes RFE may be formed on the first insulating layer IL1 (S120).

The reflective electrodes RFE may be formed in the display area DA on the first insulating layer IL1. The reflective electrodes RFE may not be formed in the dummy pixel area DUMA. The reflective electrodes RFE may be spaced apart from each other. For example, the reflective electrodes RFE may be spaced apart from each other in the second direction DR2 in the display area DA. In one or more embodiments, each of the reflection electrodes RFE may be between the connection pads CND in a plan view. In some embodiments, each of the reflection electrodes RFE may overlap a spaced area between the connection pads CND in a plan view. For example, the reflective electrode RFE may have a grid shape and/or a matrix shape in a plan view.

The second insulating layer IL2 may be formed on the first insulating layer IL1. The second insulating layer IL2 may be formed (e.g., entirely formed) over the display area DA and the dummy pixel area DUMA. The second insulating layer IL2 may cover the reflective electrode RFE.

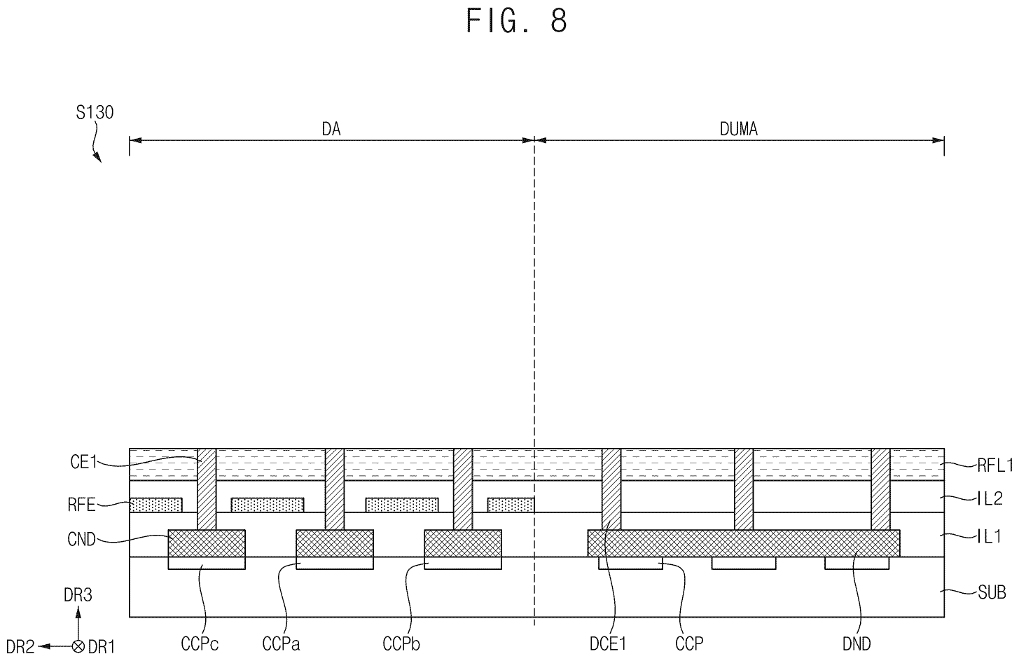

Referring to FIG. 8, the first reflective layer RFL1 may be formed on the substrate SUB (S130). For example, the first reflective layer RFL1 may be formed at an upper surface of the second insulating layer IL2.

In one or more embodiments, the first reflective layer RFL1 may be formed (e.g., entirely formed) over the display area DA and the dummy pixel area DUMA. However, the present disclosure is not limited thereto, and the first reflective layer RFL1 may be provided in only a portion of the display area DA.

For example, the first reflective layer RFL1 may include at least one lower sub-insulating layer including the first sub-layer (SUL1, refer to FIG. 4) having a first refractive index and the second sub-layer (SUL2, refer to FIG. 4) on the first sub-layer and having a second refractive index different from the first refractive index. For example, the first reflective layer RFL1 may include a distributed Bragg reflective layer in which the first sub-layer and the second sub-layer having different refractive indices are alternately and repeatedly stacked.

In one or more embodiments, as illustrated in FIG. 8, after forming the reflective electrodes RFE on the substrate SUB, the first reflective layer RFL1 may be formed on the reflective electrodes RFE. However, the present disclosure is not limited thereto. In one or more embodiments, after forming the first reflective layer RFL1 on the substrate SUB, the reflective electrodes RFE may be formed on the first reflective layer RFL1.

The first through hole that penetrates the first insulating layer IL1, the second insulating layer IL2, and the first reflective layer RFL1 in the display area DA and the first dummy through hole that penetrates the first insulating layer IL1, the second insulating layer IL2, and the first reflective layer RFL1 in the dummy pixel area DUMA may be formed. The first through hole that penetrates the first insulating layer IL1, the second insulating layer IL2, and the first reflective layer RFL1 in the display area DA may be formed between the reflective electrodes RFE in a plan view.

The first connection electrode CE1 may be formed in the display area DA on the connection pad CND. The first connection electrode CE1 may fill the inside of the first through hole that penetrates the first insulating layer IL1, the second insulating layer IL2, and the first reflective layer RFL1 in the display area DA. The first connection electrode CE1 may be formed between the reflective electrodes RFE in a plan view. The first connection electrode CE1 may contact the connection pad CND. Accordingly, the first connection electrode CE1 may be electrically connected to any one selected from among the first to third pixel driving circuits CCPa, CCPb, and CCPc.

The first dummy connection electrode DCE1 may be formed in the dummy pixel area DUMA on the dummy connection pad DND. The first dummy connection electrode DCE1 may fill the inside of the first dummy through hole that penetrates the first insulating layer IL1, the second insulating layer IL2, and the first reflective layer RFL1 in the dummy pixel area DUMA. The first dummy connection electrode DCE1 may contact the dummy connection pad DND. The first dummy connection electrode DCE1 may be formed through substantially the same process as the first connection electrode CE1.

A polishing process may be performed on the first connection electrode CE1 and the first dummy connection electrode DCE1. For example, the polishing process may be a chemical mechanical polishing (CMP) process. Accordingly, an upper surface of the first connection electrode CE1 and an upper surface of the first dummy connection electrode DCE1 may have the same (or substantially the same) level as an upper surface of the first reflective layer RFL1.

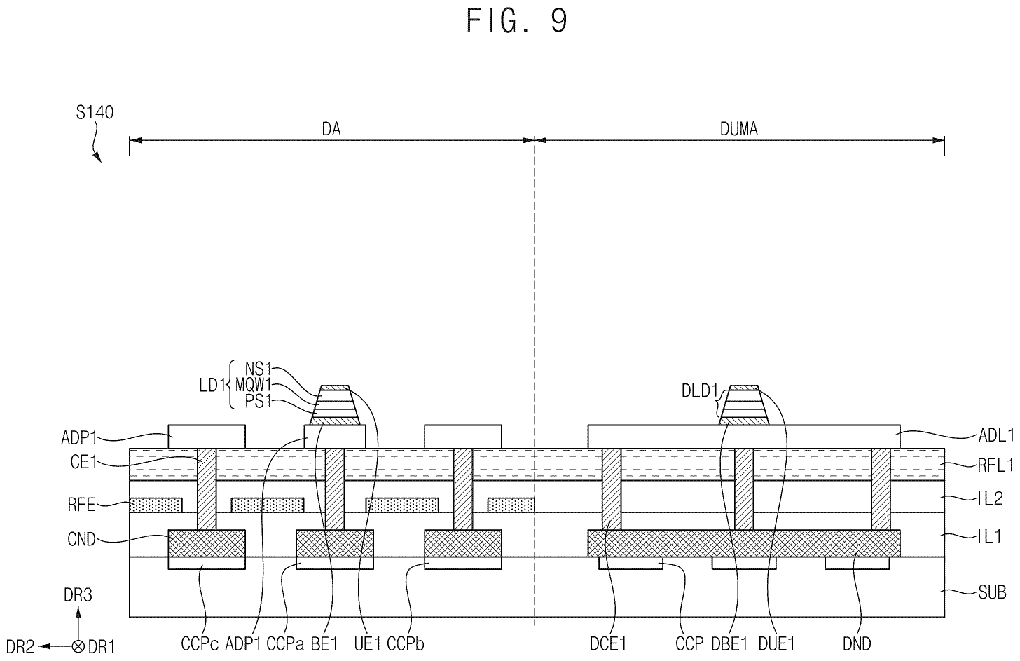

Referring to FIG. 9, the first light-emitting element LD1 may be formed on the first reflective layer RFL1 (S140). The first light-emitting element LD1 may overlap a spaced area between the reflective electrodes RFE in a plan view.

For example, after forming a first preliminary light-emitting element having an unpatterned epitaxial structure on an epitaxy substrate, the substrate SUB and the epitaxy substrate may be bonded. The first preliminary light-emitting element may include a first preliminary lower electrode, a first preliminary lower semiconductor layer, a first preliminary active layer, a first preliminary upper semiconductor layer, and a first preliminary upper electrode that are unpatterned. Accordingly, the first adhesive layer ADL1 and the first preliminary light-emitting element on the first adhesive layer ADL1 may be positioned on the first reflective layer RFL1. After the substrate SUB and the epitaxy substrate are bonded, the epitaxy substrate may be removed. For example, the epitaxy substrate may be removed through a laser lift off (LLO) process.

After the epitaxy substrate is removed, the first adhesive layer ADL1 and the first preliminary light-emitting element may be patterned to form the first adhesive patterns ADP1, the first lower electrode BE1, the first light-emitting element LD1, and the first upper electrode UE1. For example, the first adhesive pattern ADP1, the first lower electrode BE1, the first light-emitting element LD1, and the first upper electrode UE1 that are sequentially stacked along the third direction DR3 may be formed on the first reflective layer RFL1. Each of the first adhesive patterns ADP1 may contact the first connection electrode CE1. Each of the first adhesive patterns ADP1 may overlap the spaced area between the reflective electrodes RFE in a plan view.

The first light-emitting element LD1 may overlap the spaced area between the reflective electrodes RFE in a plan view. The first light-emitting element LD1 may include the first lower semiconductor layer PS1, the first active layer MQW1, and the first upper semiconductor layer NS1. The first light-emitting element LD1 may be to emit light of a first color. For example, the first light-emitting element LD1 may be to emit green light, but the present disclosure is not limited thereto. For example, each of the first lower electrode BE1, the first lower semiconductor layer PS1, the first active layer MQW1, the first upper semiconductor layer NS1, and the first upper electrode UE1 may have a tapered shape in a cross-section, but the present disclosure is not limited thereto.

In the process of patterning the first preliminary light-emitting element after the epitaxy substrate is removed, the first dummy lower electrode DBE1, the first dummy light-emitting element DLD1, and the first dummy upper electrode DUE1 may be formed concurrently (e.g., simultaneously) with the first lower electrode BE1, the first light-emitting element LD1, and the first upper electrode UE1. The first dummy lower electrode DBE1, the first dummy light-emitting element DLD1, and the first dummy upper electrode DUE1 may be formed in the dummy pixel area DUMA on the first adhesive layer ADL1. Unlike the first light-emitting element LD1, the first dummy light-emitting element DLD1 may not generate light.

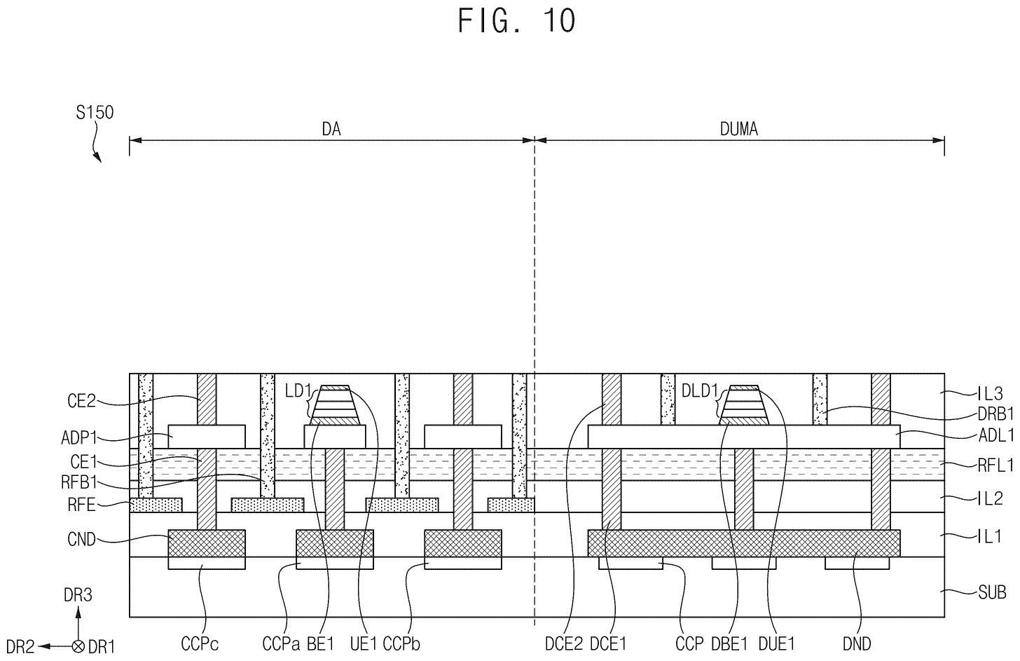

Referring to FIG. 10, a second lower contact hole that penetrates the third insulating layer IL3 may be formed at opposite sides of the first light-emitting element LD1, and the first reflective bulkhead RFB1 filling an interior of the second lower contact hole may be formed (S150).

The third insulating layer IL3 may be formed on the first reflective layer RFL1. The third insulating layer IL3 may be formed (e.g., entirely formed) over the display area DA and the dummy pixel area DUMA. The third insulating layer IL3 may cover the first adhesive pattern ADP1, the first lower electrode BE1, the first light-emitting element LD1, the first upper electrode UE1, the first dummy lower electrode DBE1, the first dummy light-emitting element DLD1, and the first dummy upper electrode DUE1.

A first lower contact hole that penetrates the third insulating layer IL3 in the display area DA and a first lower dummy contact hole that penetrates the third insulating layer IL3 in the dummy pixel area DUMA may be formed. The first lower contact hole that penetrates the third insulating layer IL3 in the display area DA may overlap the first adhesive pattern ADP1 on which the first light-emitting element LD1 is not formed in a plan view.

In one or more embodiments, the second lower contact hole that penetrates the third insulating layer IL3 in the display area DA and a second lower dummy contact hole that penetrates the third insulating layer IL3 in the dummy pixel area DUMA may be formed. The second lower contact holes that penetrates the third insulating layer IL3 in the display area DA may be formed at opposite sides of the first light-emitting element LD1, and may overlap the reflective electrode RFE in a plan view.

The second connection electrode CE2 may be formed in the display area DA on the first adhesive pattern ADP1. The second connection electrode CE2 may fill an interior of the first lower contact hole that penetrates the third insulating layer IL3 in the display area DA. The second connection electrode CE2 may contact the first adhesive pattern ADP1. Accordingly, the second connection electrode CE2 may be electrically connected to the second pixel driving circuit CCPb and/or the third pixel driving circuit CCPc.

The second dummy connection electrode DCE2 may be formed in the dummy pixel area DUMA on the first adhesive layer ADL1. The second dummy connection electrode DCE2 may fill an interior of the first lower dummy contact hole that penetrates the third insulating layer IL3 in the dummy pixel area DUMA. The second dummy connection electrode DCE2 may contact the first adhesive layer ADL1. The second dummy connection electrode DCE2 may be formed through substantially the same process as the second connection electrode CE2.

The first reflective bulkhead RFB1 may be formed in the display area DA on the reflective electrode RFE. The first reflective bulkhead RFB1 may fill an interior of the second lower contact hole that penetrates the third insulating layer IL3 in the display area DA. Accordingly, the first reflective bulkhead RFB1 may be spaced apart from the first light-emitting element LD1, and may be provided at opposite sides of the first light-emitting element LD1.

In one or more embodiments, as illustrated in FIG. 10, the first reflective bulkhead RFB1 may contact the reflective electrode RFE. In this case, the first reflective bulkhead RFB1 may penetrate the second insulating layer IL2, the first reflective layer RFL1, and the third insulating layer IL3 in the display area DA. However, the present disclosure is not limited thereto.

In one or more embodiments, the first reflective bulkhead RFB1 may be spaced apart from the reflective electrode RFE. In this case, the first reflective bulkhead RFB1 may penetrate the third insulating layer IL3 in the display area DA, and may not penetrate the first reflective layer RFL1 and the second insulating layer IL2.

The first dummy reflective bulkhead DRB1 may be formed in the dummy pixel area DUMA on the first adhesive layer ADL1. The first dummy reflective bulkhead DRB1 may fill an interior of the second lower dummy contact hole that penetrates the third insulating layer IL3 in the dummy pixel area DUMA. The first dummy reflective bulkhead DRB1 may be formed through substantially the same process as the first reflective bulkhead RFB1.

A polishing process may be performed on the second connection electrode CE2, the second dummy connection electrode DCE2, the first reflective bulkhead RFB1, and the first dummy reflective bulkhead DRB1. Accordingly, an upper surface of the second connection electrode CE2, an upper surface of the second dummy connection electrode DCE2, an upper surface of the first reflective bulkhead RFB1, and an upper surface of the first dummy reflective bulkhead DRB1 may have the same level as an upper surface of the third insulating layer IL3.

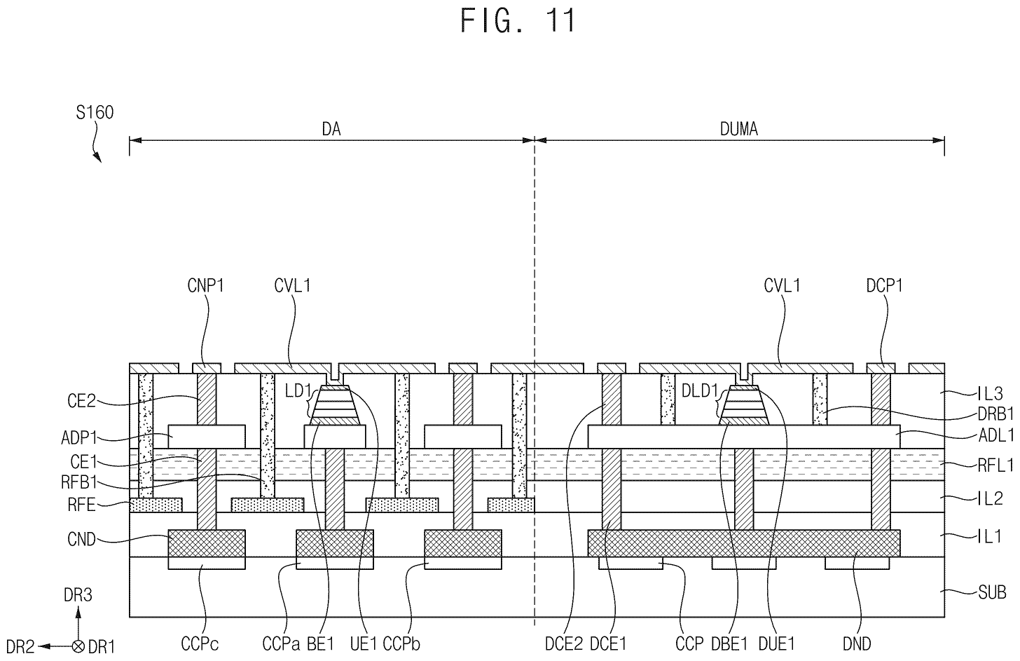

Referring to FIG. 11, the first common voltage line CVL1 may be formed on the first upper electrode UE1 and the first dummy upper electrode DUE1 (S160). The first common voltage line CVL1 may be connected to the first upper electrode UE1 and the first dummy upper electrode DUE1 through an opening defined by the third insulating layer IL3.

The first connection pattern CNP1 and the first dummy connection pattern DCP1 may be formed on the third insulating layer IL3. The first connection pattern CNP1 may be formed in the display area DA, and the first dummy connection pattern DCP1 may be formed in the dummy pixel area DUMA. The first connection pattern CNP1 and the first dummy connection pattern DCP1 may be formed through substantially the same process as the first common voltage line CVL1. The first connection pattern CNP1 and the first dummy connection pattern DCP1 may be electrically independent from the first common voltage line CVL1.

Referring to FIG. 12, the second reflective layer RFL2 may be formed on the third insulating layer IL3 that covers the first light-emitting element LD1 (S210). For example, the second reflective layer RFL2 may be formed at an upper surface of the fourth insulating layer IL4.

The fourth insulating layer IL4 may be formed on the third insulating layer IL3. The fourth insulating layer IL4 may be formed (e.g., entirely formed) over the display area DA and the dummy pixel area DUMA. The fourth insulating layer IL4 may cover the first common voltage line CVL1, the first connection pattern CNP1, and the first dummy connection pattern DCP1.

The second reflective layer RFL2 may be formed at the upper surface of the fourth insulating layer IL4. In one or more embodiments, the second reflective layer RFL2 may be formed in a portion of the display area DA and a portion of the dummy pixel area DUMA. However, the present disclosure is not limited thereto, and the second reflective layer RFL2 may not be formed in the dummy pixel area DUMA.

For example, the second reflective layer RFL2 may include at least one middle sub-insulating layer including the first sub-layer (SUL1, refer to FIG. 4) and the second sub-layer (SUL2, refer to FIG. 4) on the first sub-layer. For example, the second reflective layer RFL2 may include a distributed Bragg reflective layer in which the first sub-layer and the second sub-layer having different refractive indices are alternately and repeatedly stacked.

The fifth insulating layer IL5 may be formed on the fourth insulating layer IL4. The fifth insulating layer IL5 may be formed (e.g., entirely formed) over the display area DA and the dummy pixel area DUMA. The fifth insulating layer IL5 may cover the second reflective layer RFL2.

A second through hole that penetrates the fourth insulating layer IL4, the second reflective layer RFL2, and the fifth insulating layer IL5 in the display area DA and a second dummy through hole that penetrates the fourth insulating layer IL4, the second reflective layer RFL2, and the fifth insulating layer IL5 in the dummy pixel area DUMA may be formed.

The third connection electrode CE3 may be formed in the display area DA on the first connection pattern CNP1. The third connection electrode CE3 may fill an interior of the second through hole that penetrates the fourth insulating layer IL4, the second reflective layer RFL2, and the fifth insulating layer IL5 in the display area DA. The third connection electrode CE3 may contact the first connection pattern CNP1 that is electrically connected to the second pixel driving circuit CCPb.

The third dummy connection electrode DCE3 may be formed in the dummy pixel area DUMA on the first dummy connection pattern DCP1. The third dummy connection electrode DCE3 may fill an interior of the second dummy through hole that penetrates the fourth insulating layer IL4, the second reflective layer RFL2, and the fifth insulating layer IL5 in the dummy pixel area DUMA. The third dummy connection electrode DCE3 may contact the first dummy connection pattern DCP1. The third dummy connection electrode DCE3 may be formed through substantially the same process as the third connection electrode CE3.

A polishing process may be performed on the third connection electrode CE3 and the third dummy connection electrode DCE3. Accordingly, an upper surface of the third connection electrode CE3 and an upper surface of the third dummy connection electrode DCE3 may have substantially the same level as an upper surface of the fifth insulating layer IL5.

Referring to FIG. 13, the second light-emitting element LD2 may be formed on the second reflective layer RFL2 (S220). The second light-emitting element LD2 may overlap the second reflective layer RFL2 in a plan view.

A method of forming the second adhesive pattern ADP2, the second lower electrode BE2, the second light-emitting element LD2, and the second upper electrode UE2 may be substantially the same as a method of forming the first adhesive pattern ADP1, the first lower electrode BE1, the first light-emitting element LD1, and the first upper electrode UE1. For example, after forming a second preliminary light-emitting element on an epitaxy substrate, the substrate SUB and the epitaxy substrate may be bonded. Thereafter, the epitaxy substrate may be removed, and the second preliminary light-emitting element may be patterned to form the second lower electrode BE2, the second light-emitting element LD2, and the second upper electrode UE2. Hereinafter, redundant descriptions of the method of forming the first adhesive pattern ADP1, the first lower electrode BE1, the first light-emitting element LD1, and the first upper electrode UE1 may not be provided or may be summarized.

The second adhesive pattern ADP2 may contact the third connection electrode CE3 in the display area DA. The second adhesive pattern ADP2 may overlap the spaced area between the reflective electrodes RFE in the display area DA in a plan view. The second adhesive pattern ADP2 may contact the third dummy connection electrode DCE3 in the dummy pixel area DUMA.

The second light-emitting element LD2 may overlap the spaced area between the reflective electrodes RFE in a plan view. The second light-emitting element LD2 may include the second lower semiconductor layer PS2, the second active layer MQW2, and the second upper semiconductor layer NS2. The second light-emitting element LD2 may be to emit light of a second color different from the first color. For example, the second light-emitting element LD2 may be to emit blue light, but the present disclosure is not limited thereto.

In the process of patterning the second preliminary light-emitting element after the epitaxy substrate is removed, the second dummy lower electrode DBE2, the second dummy light-emitting element DLD2, and the second dummy upper electrode DUE2 may be formed concurrently (e.g., simultaneously) with the second lower electrode BE2, the second light-emitting element LD2, and the second upper electrode UE2. The second dummy lower electrode DBE2, the second dummy light-emitting element DLD2, and the second dummy upper electrode DUE2 may be formed in the dummy pixel area DUMA on the second adhesive pattern ADP2. Unlike the second light-emitting element LD2, the second dummy light-emitting element DLD2 may not generate light.

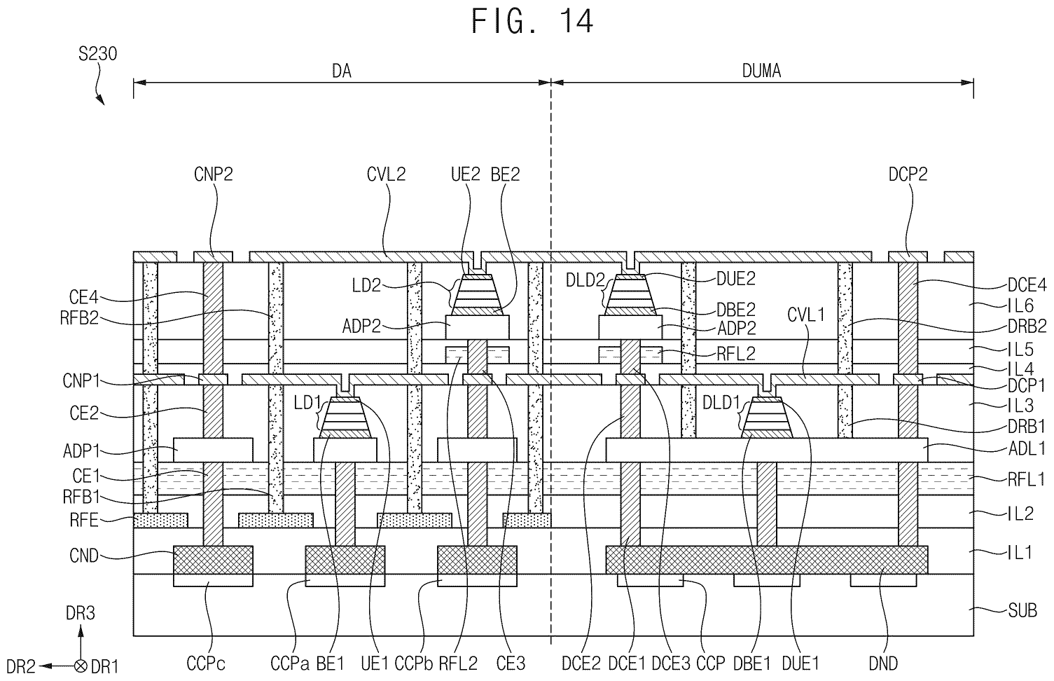

Referring to FIG. 14, a second middle contact hole that penetrates the sixth insulating layer IL6, which covers the second light-emitting element LD2, may be formed, and the second reflective bulkhead RFB2 that fills an interior of the second middle contact hole may be formed (S230).

The sixth insulating layer IL6 may be formed on the fifth insulating layer IL5. The sixth insulating layer IL6 may be entirely formed over the display area DA and the dummy pixel area DUMA. The sixth insulating layer IL6 may cover the second adhesive pattern ADP2, the second lower electrode BE2, the second light-emitting element LD2, the second upper electrode UE2, the second dummy lower electrode DBE2, the second dummy light-emitting element DLD2, and the second dummy upper electrode DUE2.

A first middle contact hole that penetrates the fourth insulating layer IL4, the fifth insulating layer IL5, and the sixth insulating layer IL6 in the display area DA and a first middle dummy contact hole that penetrates the fourth insulating layer IL4, the fifth insulating layer IL5, and the sixth insulating layer IL6 in the dummy pixel area DUMA may be formed. The first middle contact hole that penetrates the fourth insulating layer IL4, the fifth insulating layer IL5, and the sixth insulating layer IL6 in the display area DA may overlap the first connection pattern CNP1 that is electrically connected to the third pixel driving circuit CCPc in a plan view.

In one or more embodiments, the second middle contact hole that penetrates the fourth insulating layer IL4, the fifth insulating layer IL5, and the sixth insulating layer IL6 in the display area DA and a second middle dummy contact holes that penetrates the fourth insulating layer IL4, the fifth insulating layer IL5, and the sixth insulating layer IL6 in the dummy pixel area DUMA may be formed. The second middle contact hole that penetrates the fourth insulating layer IL4, the fifth insulating layer IL5, and the sixth insulating layer IL6 in the display area DA may be formed at opposite sides of the second light-emitting element LD2, and may overlap the reflective electrode RFE in a plan view.

The fourth connection electrode CE4 may be formed in the display area DA on the first connection pattern CNP1. The fourth connection electrode CE4 may fill an interior of the first middle contact hole that penetrates the fourth insulating layer IL4, the fifth insulating layer IL5, and the sixth insulating layer IL6 in the display area DA. The fourth connection electrode CE4 may contact the first connection pattern CNP1. Accordingly, the fourth connection electrode CE4 may be electrically connected to the third pixel driving circuit CCPc.

The fourth dummy connection electrode DCE4 may be formed in the dummy pixel area DUMA on the first dummy connection pattern DCP1. The fourth dummy connection electrode DCE4 may fill an interior of the first middle dummy contact hole that penetrates the fourth insulating layer IL4, the fifth insulating layer IL5, and the sixth insulating layer IL6 in the dummy pixel area DUMA. The fourth dummy connection electrode DCE4 may contact the first dummy connection pattern DCP1. The fourth dummy connection electrode DCE4 may be formed through substantially the same process as the fourth connection electrode CE4.

The second reflective bulkhead RFB2 may be formed in the display area DA on the first common voltage line CVL1. The second reflective bulkhead RFB2 may fill the interior of the second middle contact hole that penetrates the fourth insulating layer IL4, the fifth insulating layer IL5, and the sixth insulating layer IL6 in the display area DA. Accordingly, the second reflective bulkhead RFB2 may be spaced apart from the second light-emitting element LD2, and may be provided at opposite sides of the second light-emitting element LD2. The second reflective bulkhead RFB2 may be positioned at the same line as the first reflective bulkhead RFB1 in a cross-section.

The second dummy reflective bulkhead DRB2 may be formed in the dummy pixel area DUMA on the first common voltage line CVL1. The second dummy reflective bulkhead DRB2 may fill an interior of the second middle dummy contact hole that penetrates the fourth insulating layer IL4, the fifth insulating layer IL5, and the sixth insulating layer IL6 in the dummy pixel area DUMA. The second dummy reflective bulkhead DRB2 may be formed through substantially the same process as the second reflective bulkhead RFB2.

A polishing process may be performed on the fourth connection electrode CE4, the fourth dummy connection electrode DCE4, the second reflective bulkhead RFB2, and the second dummy reflective bulkhead DRB2. Accordingly, an upper surface of the fourth connection electrode CE4, an upper surface of the fourth dummy connection electrode DCE4, an upper surface of the second reflective bulkhead RFB2, and an upper surface of the second dummy reflective bulkhead DRB2 may have substantially the same level as an upper surface of the sixth insulating layer IL6.

The second common voltage line CVL2 may be formed on the second upper electrode UE2 and the second dummy upper electrode DUE2. The second common voltage line CVL2 may be connected to the second upper electrode UE2 and the second dummy upper electrode DUE2 through an opening defined by the sixth insulating layer IL6.

The second connection pattern CNP2 and the second dummy connection pattern DCP2 may be formed on the sixth insulating layer IL6. The second connection pattern CNP2 may be formed in the display area DA, and the second dummy connection pattern DCP2 may be formed in the dummy pixel area DUMA. The second connection pattern CNP2 and the second dummy connection pattern DCP2 may be formed through substantially the same process as the second common voltage line CVL2. The second connection pattern CNP2 and the second dummy connection pattern DCP2 may be electrically independent from the second common voltage line CVL2.

Referring to FIG. 15, the third reflective layer RFL3 may be formed on the sixth insulating layer IL6 that covers the second light-emitting element LD2 (S310). For example, the third reflective layer RFL3 may be formed at an upper surface of the seventh insulating layer IL7.

The seventh insulating layer IL7 may be formed on the sixth insulating layer IL6. The seventh insulating layer IL7 may be entirely formed over the display area DA and the dummy pixel area DUMA. The seventh insulating layer IL7 may cover the second common voltage line CVL2, the second connection pattern CNP2, and the second dummy connection pattern DCP2.

The third reflective layer RFL3 may be formed at the upper surface of the seventh insulating layer IL7. In one or more embodiments, the third reflective layer RFL3 may be formed in a portion of the display area DA and a portion of the dummy pixel area DUMA. However, the present disclosure is not limited thereto, and the third reflective layer RFL3 may not be formed in the dummy pixel area DUMA.

For example, the third reflective layer RFL3 may include at least one upper sub-insulating layer including the first sub-layer (SUL1, refer to FIG. 4) and the second sub-layer (SUL2, refer to FIG. 4) on the first sub-layer. For example, the third reflective layer RFL3 may include a distributed Bragg reflective layer in which the first sub-layer and the second sub-layer having different refractive indices are alternately and repeatedly stacked.

The eighth insulating layer IL8 may be formed on the seventh insulating layer IL7. The eighth insulating layer IL8 may be formed (e.g., entirely formed) over the display area DA and the dummy pixel area DUMA. The eighth insulating layer IL8 may cover the third reflective layer RFL3.

A third through hole that penetrates the seventh insulating layer IL7, the third reflective layer RFL3, and the eighth insulating layer IL8 in the display area DA and a third dummy through hole that penetrates the seventh insulating layer IL7, the third reflective layer RFL3, and the eighth insulating layer IL8 in the dummy pixel area DUMA may be formed.

The fifth connection electrode CE5 may be formed in the display area DA on the second connection pattern CNP2. The fifth connection electrode CE5 may fill an interior of the third through hole that penetrates the seventh insulating layer IL7, the third reflective layer RFL3, and the eighth insulating layer IL8 in the display area DA. The fifth connection electrode CE5 may contact the second connection pattern CNP2 that is electrically connected to the third pixel driving circuit CCPc.

The fifth dummy connection electrode DCE5 may be formed in the dummy pixel area DUMA on the second dummy connection pattern DCP2. The fifth dummy connection electrode DCE5 may fill an interior of the third dummy through hole that penetrates the seventh insulating layer IL7, the third reflective layer RFL3, and the eighth insulating layer IL8 in the dummy pixel area DUMA. The fifth dummy connection electrode DCE5 may contact the second dummy connection pattern DCP2. The fifth dummy connection electrode DCE5 may be formed through substantially the same process as the fifth connection electrode CE5.

A polishing process may be performed on the fifth connection electrode CE5 and the fifth dummy connection electrode DCE5. Accordingly, an upper surface of the fifth connection electrode CE5 and an upper surface of the fifth dummy connection electrode DCE5 may have the same level as an upper surface of the eighth insulating layer IL8.

Referring to FIG. 16, the third light-emitting element LD3 may be formed on the third reflective layer RFL3 (S320). The third light-emitting element LD3 may overlap the third reflective layer RFL3 in a plan view.

A method of forming the third adhesive pattern ADP3, the third lower electrode BE3, the third light-emitting element LD3, and the third upper electrode UE3 may be substantially the same as the method of forming the first adhesive pattern ADP1, the first lower electrode BE1, the first light-emitting element LD1, and the first upper electrode UE1. For example, after forming a third preliminary light-emitting element on an epitaxy substrate, the substrate SUB and the epitaxy substrate may be bonded. Thereafter, the epitaxy substrate may be removed, and the third preliminary light-emitting element may be patterned to form the third lower electrode BE3, the third light-emitting element LD3, and the third upper electrode UE3. Hereinafter, redundant descriptions of the method of forming the first adhesive pattern ADP1, the first lower electrode BE1, the first light-emitting element LD1, and the first upper electrode UE1 may not be provided or may be summarized.

The third adhesive pattern ADP3 may contact the fifth connection electrode CE5 in the display area DA. The third adhesive pattern ADP3 may overlap the spaced area between the reflective electrodes RFE in the display area DA in a plan view. The third adhesive pattern ADP3 may contact the fifth dummy connection electrode DCE5 in the dummy pixel area DUMA.

The third light-emitting element LD3 may overlap the spaced area between the reflective electrodes RFE in a plan view. The third light-emitting element LD3 may include the third lower semiconductor layer PS3, the third active layer MQW3, and the third upper semiconductor layer NS3. The third light-emitting element LD3 may be to emit light of a third color different from the first color and the second color. For example, the third light-emitting element LD3 may be to emit red light, but the present disclosure is not limited thereto.

In the process of patterning the third preliminary light-emitting element after the epitaxy substrate is removed, the third dummy lower electrode DBE3, the third dummy light-emitting element DLD3, and the third dummy upper electrode DUE3 may be formed concurrently (e.g., simultaneously) with the third lower electrode BE3, the third light-emitting element LD3, and the third upper electrode UE3. The third dummy lower electrode DBE3, the third dummy light-emitting element DLD3, and the third dummy upper electrode DUE3 may be formed in the dummy pixel area DUMA on the third adhesive pattern ADP3. Unlike the third light-emitting element LD3, the third dummy light-emitting element DLD3 may not generate light.

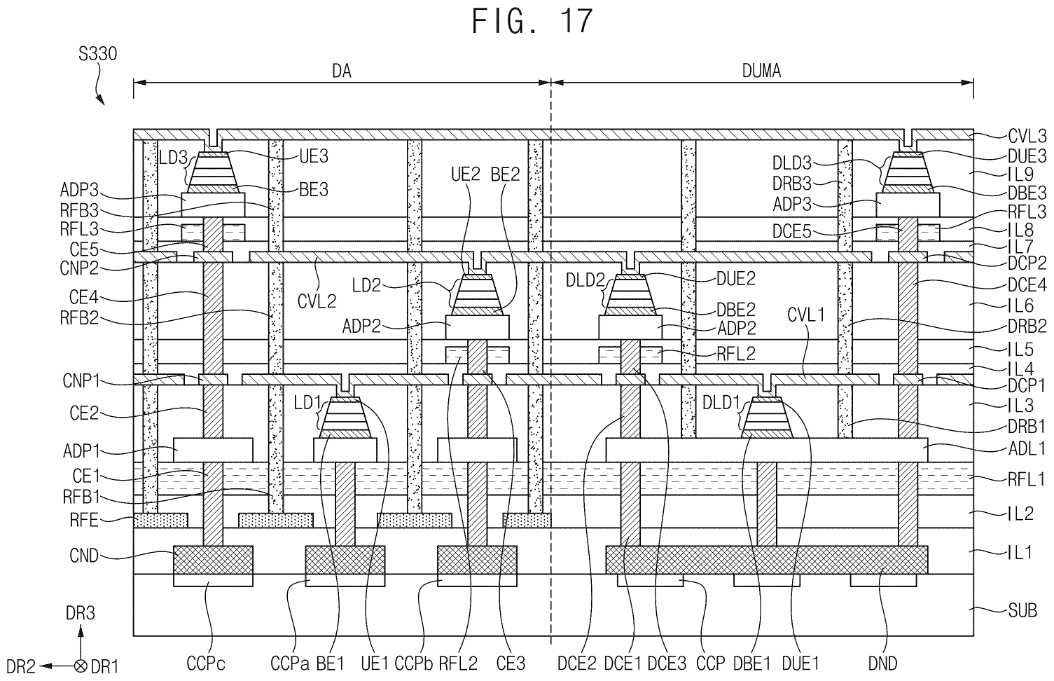

Referring to FIG. 17, an upper contact hole that penetrates the ninth insulating layer IL9, which covers the third light-emitting element LD3, may be formed, and the third reflective bulkhead RFB3 that fills an interior of the upper contact hole may be formed (S330).

The ninth insulating layer IL9 may be formed on the eighth insulating layer IL8. The ninth insulating layer IL9 may be formed (e.g., entirely formed) over the display area DA and the dummy pixel area DUMA. The ninth insulating layer IL9 may cover the third adhesive pattern ADP3, the third lower electrode BE3, the third light-emitting element LD3, the third upper electrode UE3, the third dummy lower electrode DBE3, the third dummy light-emitting element DLD3, and the third dummy upper electrode DUE3.

The upper contact hole that penetrates the seventh insulating layer IL7, the eighth insulating layer IL8, and the ninth insulating layer IL9 in the display area DA and an upper dummy contact hole that penetrates the seventh insulating layer IL7, the eighth insulating layer IL8, and the ninth insulating layer IL9 in the dummy pixel area DUMA may be formed. The upper contact hole that penetrates the seventh insulating layer IL7, the eighth insulating layer IL8, and the ninth insulating layer IL9 may be formed at opposite sides of the third light-emitting element LD3, and may overlap the reflective electrode RFE in a plan view.

The third reflective bulkhead RFB3 may be formed in the display area DA on the second common voltage line CVL2. The third reflective bulkhead RFB3 may fill the interior of the upper contact hole that penetrates the seventh insulating layer IL7, the eighth insulating layer IL8, and the ninth insulating layer IL9 in the display area DA. Accordingly, the third reflective bulkhead RFB3 may be spaced apart from the third light-emitting element LD3, and may be provided at opposite sides of the third light-emitting element LD3 (e.g., along the second direction DR2). The third reflective bulkhead RFB3 may be positioned at (e.g., along) the same line as the first reflective bulkhead RFB1 and the second reflective bulkhead RFB2 in a cross-section.

The third dummy reflective bulkhead DRB3 may be formed in the dummy pixel area DUMA on the second common voltage line CVL2. The third dummy reflective bulkhead DRB3 may fill an interior of the upper dummy contact hole that penetrates the seventh insulating layer IL7, the eighth insulating layer IL8, and the ninth insulating layer IL9 in the dummy pixel area DUMA. The third dummy reflective bulkhead DRB3 may be formed through substantially the same process as the third reflective bulkhead RFB3.

A polishing process may be performed on the third reflective bulkhead RFB3 and the third dummy reflective bulkhead DRB3. Accordingly, an upper surface of the third reflective bulkhead RFB3 and an upper surface of the third dummy reflective bulkhead DRB3 may have substantially the same level as an upper surface of the ninth insulating layer IL9.

The third common voltage line CVL3 may be formed on the third upper electrode UE3 and the third dummy upper electrode DUE3. The third common voltage line CVL3 may be connected to the third upper electrode UE3 and the third dummy upper electrode DUE3 through an opening defined by the ninth insulating layer IL9.

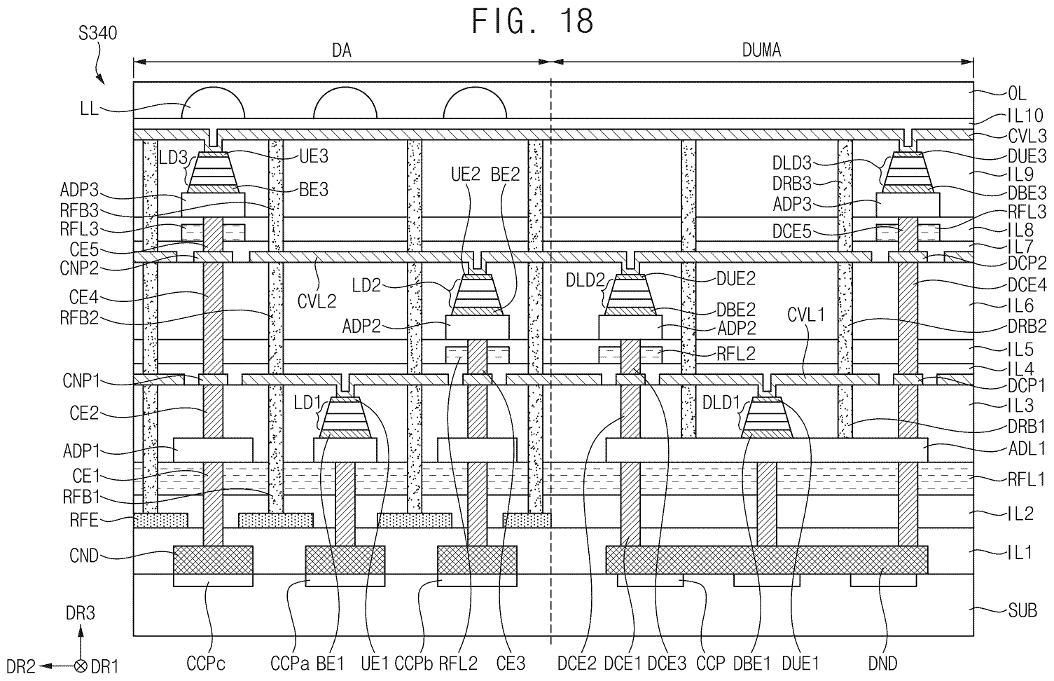

Referring to FIG. 18, the lens layer LL may be formed on the third light-emitting element LD3 (S340). For example, the lens layer LL may be formed at an upper surface of the tenth insulating layer IL10.

The tenth insulating layer IL10 may be formed on the ninth insulating layer IL9. The tenth insulating layer IL10 may be formed (e.g., entirely formed) over the display area DA and the dummy pixel area DUMA. The tenth insulating layer IL10 may cover the third common voltage line CVL3.

The lens layer LL may be formed in the display area DA on the tenth insulating layer IL10. The lens layer LL may include the micro lenses in the display area DA. The micro lenses may overlap the first light-emitting element LD1, the second light-emitting element LD2, and the third light-emitting element LD3 in a plan view, respectively.

The filling layer OL may be formed on the lens layer LL. The filling layer OL may be formed in the display area DA and the dummy pixel area DUMA. The filling layer OL may flatten (e.g., substantially planarize) the step difference of the lens layer LL.

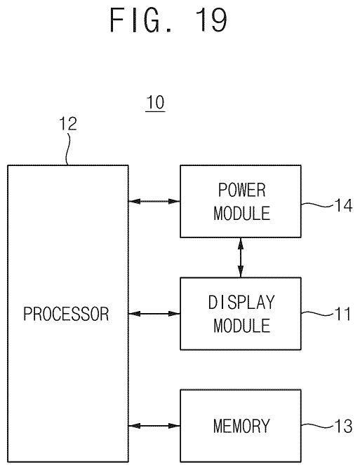

FIG. 19 is a block or reduce diagram of an electronic device according to one or more embodiments of the present disclosure.

Referring to FIG. 19, an electronic device 10 according to one or more embodiments may include a display module 11, a processor 12, a memory 13, and a power module 14. The display device according to one or more embodiments may be applied to a variety of electronic devices. The electronic device 10 may include the display device according to one or more embodiments, and may further include modules and/or devices having other additional functions in addition to the display device.

The processor 12 may include at least one selected from a central processing unit (CPU), an application processor (AP), a graphic processing unit (GPU), a communication processor (CP), an image signal processor (ISP), and a controller.

The memory 13 may store data information desired or required for operation of the processor 12 and/or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter, a battery device, and/or the like, and a power conversion module that converts power supplied by the power supply module to generate the power desired or required for operation of the electronic device 10. For example, the power module 14 may provide power to the display device according to the embodiments described herein.

At least one of the components of the electronic device 10 described herein may be included in the display device according to the present embodiments. In one or more embodiments, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

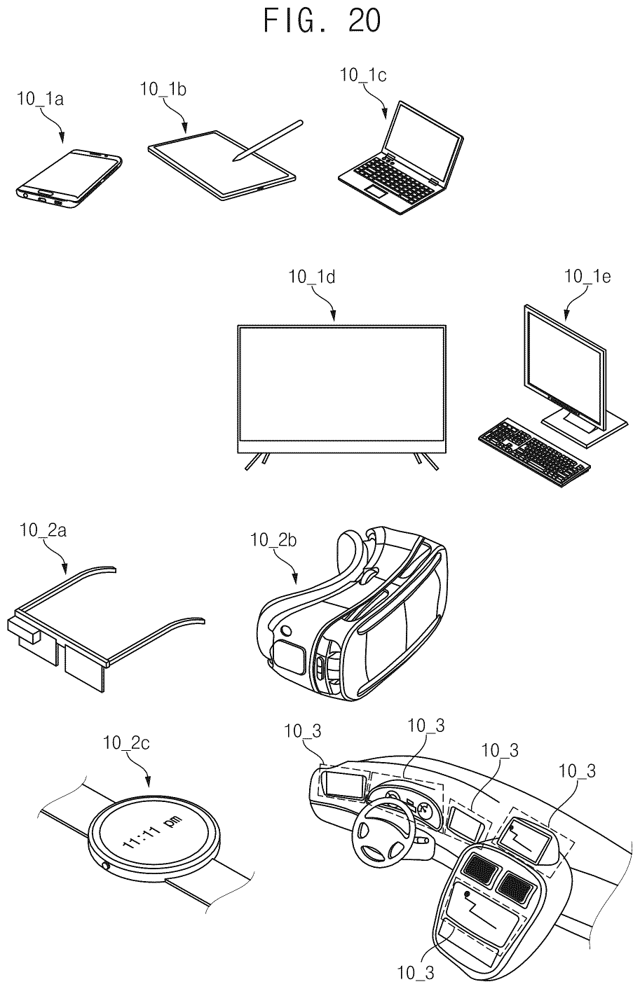

FIG. 20 is a schematic diagram, each illustrating an electronic device according to one or more suitable embodiments.

Referring to FIG. 20, one or more suitable electronic devices to which a display device according to the embodiments is applied may include image display electronic devices such as a smartphone 10_1a, a tablet PC 10_1b, a laptop 10_1c, a television 10_1d, a desk monitor 10_1e, and/or the like, wearable electronic devices including display modules such as a smart glasses 10_2a, a head-mounted display 10_2b, a smart watch 10_2c, and/or the like, and vehicle electronic devices 10_3 including display modules such as a CID (center information display) which may be on an instrument panel, a center fascia, a dashboard of an automobile, a room mirror display, and/or the like.

The present disclosure may be applied to one or more suitable display devices. For example, the present disclosure is applicable to one or more suitable display devices such as display devices for vehicles, ships and/or aircraft, portable communication devices, display devices for exhibition and/or information transmission, medical display devices, and/or the like.

The foregoing is illustrative of the embodiments of the present disclosure, and is not to be construed as limiting thereof. Although a few embodiments have been described with reference to the drawings, those skilled in the art will readily appreciate that many variations and modifications may be made therein without departing from the spirit and scope of the present disclosure as defined in the appended claims and their equivalents.

What is claimed is:

1. A display device comprising:
a substrate;
a first reflective layer on the substrate and comprising at least one lower sub-insulating layer which comprises a first sub-layer having a first refractive index and a second sub-layer on the first sub-layer and having a second refractive index different from the first refractive index;
a first light-emitting element on the first reflective layer and configured to emit light of a first color;
a first reflective bulkhead spaced apart from the first light-emitting element and provided at opposite sides of the first light-emitting element; and
a reflective electrode under the first light-emitting element and overlapping the first reflective bulkhead in a plan view.

2. The display device of claim 1, wherein the reflective electrode overlaps a spaced area between the first light-emitting element and the first reflective bulkhead in the plan view.

3. The display device of claim 1, further comprising:
a first adhesive pattern between the first reflective layer and the first light-emitting element.

4. The display device of claim 3, wherein the reflective electrode overlaps a spaced area between the first adhesive pattern and the first reflective bulkhead in the plan view.

5. The display device of claim 3, wherein the first adhesive pattern is spaced apart from the first reflective bulkhead.

6. The display device of claim 3, wherein the first adhesive pattern comprises a conductive material.

7. The display device of claim 1, wherein the first reflective layer overlaps the first light-emitting element in the plan view.

8. The display device of claim 1, wherein the reflective electrode is under the first reflective layer.

9. The display device of claim 1, wherein the reflective electrode is on the first reflective layer.

10. The display device of claim 1, wherein the reflective electrode contacts the first reflective bulkhead.

11. The display device of claim 1, further comprising:
a second light-emitting element on the first light-emitting element and configured to emit light of a second color different from the first color;
a second reflective bulkhead spaced apart from the second light-emitting element and provided at opposite sides of the second light-emitting element; and
a second reflective layer between the first light-emitting element and the second light-emitting element, the second reflective layer overlapping the second light-emitting element in the plan view, and comprising at least one middle sub-insulating layer which comprises the first sub-layer and the second sub-layer on the first sub-layer.

12. The display device of claim 11, further comprising:
a third light-emitting element on the second light-emitting element and configured to emit light of a third color different from the first color and the second color;
a third reflective bulkhead spaced apart from the third light-emitting element and provided at opposite sides of the third light-emitting element; and
a third reflective layer between the second light-emitting element and the third light-emitting element, the third reflective layer overlapping the third light-emitting element in the plan view, and comprising at least one upper sub-insulating layer which comprises the first sub-layer and the second sub-layer on the first sub-layer.

13. The display device of claim 12, wherein the first reflective layer overlaps the first light-emitting element, the second light-emitting element, and the third light-emitting element in the plan view.

14. The display device of claim 12, wherein the first reflective layer overlaps the first light-emitting element in the plan view and does not overlap the second light-emitting element and the third light-emitting element in the plan view.

15. A method of manufacturing a display device, the method comprising:
forming reflective electrodes spaced apart from each other on a substrate;
forming a first reflective layer comprising at least one lower sub-insulating layer which comprises a first sub-layer having a first refractive index and a second sub-layer on the first sub-layer and having a second refractive index different from the first refractive index on the substrate;
forming a first light-emitting element configured to emit light of a first color on the first reflective layer so as to overlap a spaced area between the reflective electrodes in a plan view;
forming a first insulating layer covering the first light-emitting element on the first reflective layer;
forming a lower contact hole which penetrates the first insulating layer at opposite sides of the first light-emitting element; and
forming a first reflective bulkhead which fills an interior of the lower contact hole.

16. The method of claim 15, wherein the first reflective layer is formed on the reflective electrodes after forming the reflective electrodes on the substrate.

17. The method of claim 15, wherein the reflective electrodes are formed on the first reflective layer after forming the first reflective layer on the substrate.

18. The method of claim 15, further comprising:
forming a first adhesive pattern on the first reflective layer,
wherein the first adhesive pattern is between at least one of the reflective electrodes and the first light-emitting element.

19. The method of claim 18, wherein at least one of the reflective electrodes overlaps a spaced area between the first adhesive pattern and the first reflective bulkhead in the plan view.

20. An electronic device comprising:
a display device comprising a light-emitting element; and
a processor configured to transmit an image data signal and an input control signal to the display device,
wherein the display device comprises:
a substrate;
a first reflective layer on the substrate and comprising at least one lower sub-insulating layer which comprises a first sub-layer having a first refractive index and a second sub-layer on the first sub-layer and having a second refractive index different from the first refractive index;
the light-emitting element on the first reflective layer and configured to emit light;
a first reflective bulkhead spaced apart from the light-emitting element and provided at opposite sides of the light-emitting element; and
a reflective electrode under the light-emitting element and overlapping the first reflective bulkhead in a plan view.
